(19) United States
(12) Patent Application Publication
(10) Pub. No.: US 2024/0312999 A1
(43) Pub. Date: Sep. 19, 2024

(54) SEMICONDUCTOR DEVICE

(71) Applicant: Japan Display Inc., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP)

(21) Appl. No.: 18/588,249

(22) Filed: Feb. 27, 2024

(30) Foreign Application Priority Data
Mar. 16, 2023 (JP) 2023-042011

(51) Int. Cl. H01L 27/12

(52) U.S. Cl. CPC H01L 27/1225; H01L 27/1251

(57) ABSTRACT

A semiconductor device includes a first transistor on a substrate and a second transistor on the first transistor. The first transistor includes a first gate electrode on the substrate, a first insulating film on the first gate electrode, a first oxide semiconductor layer on the first insulating film, having a region overlapping the first gate electrode, and having a polycrystalline structure, a second insulating film on the first oxide semiconductor layer, and a second gate electrode on the second insulating film. The second transistor includes a third gate electrode on the second insulating film, a third insulating film on the third gate electrode, a second oxide semiconductor layer on the third insulating film and having a region overlapping the third gate electrode, a fourth insulating film on the second oxide semiconductor layer, and a fourth gate electrode on the fourth insulating film.

### CROSS-REFERENCE TO RELATED APPLICATIONS

This application claims the benefit of priority to Japanese Patent Application No. 2023-042011, filed on Mar. 16, 2023, the entire contents of which are incorporated herein by reference.

### FIELD

An embodiment of the present invention relates to a semiconductor device and a method for manufacturing the semiconductor device. In particular, an embodiment of the present invention relates to a semiconductor device in which a transistor in which an oxide semiconductor is used as a channel is stacked, and a method for manufacturing the semiconductor device.

### BACKGROUND

In recent years, development of a semiconductor device in which an oxide semiconductor is used as a channel in place of amorphous silicon, low-temperature polysilicon, and single-crystal silicon is advancing (for example, Japanese Laid-Open Patent Publication No. 2021-141338). The field-effect mobility of a thin film transistor including a conventional oxide semiconductor layer is not so large even if an oxide semiconductor layer having crystallinity is used. Therefore, a semiconductor device has been studied in which a transistor in which crystalline silicon is used as a channel is used for a transistor that is required to be driven at high speed, and an oxide semiconductor is used for a transistor in which an off-state current is required to be low (for example, Japanese Laid-Open Patent Publication No. 2013-008946 and Japanese Laid-Open Patent Publication No. 2011-142621).

### SUMMARY

A semiconductor device according to an embodiment of the present invention includes a first transistor arranged on a substrate, and a second transistor arranged on the first transistor. The first transistor includes a first gate electrode arranged on the substrate, a first insulating film arranged on the first gate electrode, a first oxide semiconductor layer arranged on the first insulating film, having a region overlapping the first gate electrode, and having a polycrystalline structure, a second insulating film arranged on the first oxide semiconductor layer, and a second gate electrode arranged on the second insulating film. The second transistor includes a third gate electrode arranged on the second insulating film, a third insulating film arranged on the third gate electrode, a second oxide semiconductor layer arranged on the third insulating film and having a region overlapping the third gate electrode, a fourth insulating film arranged on the second oxide semiconductor layer, and a fourth gate electrode arranged on the fourth insulating film.

### BRIEF DESCRIPTION OF DRAWINGS

FIG. 1 is a cross-sectional view showing an outline of a semiconductor device according to an embodiment of the present invention.

FIG. 2 is a sequence diagram showing a method for manufacturing a semiconductor device according to an embodiment of the present invention.

FIG. 3 is a sequence diagram showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

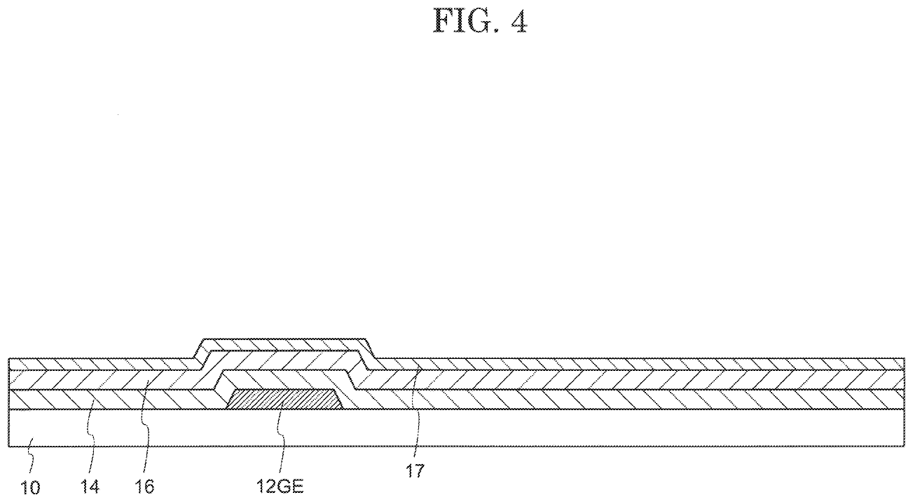

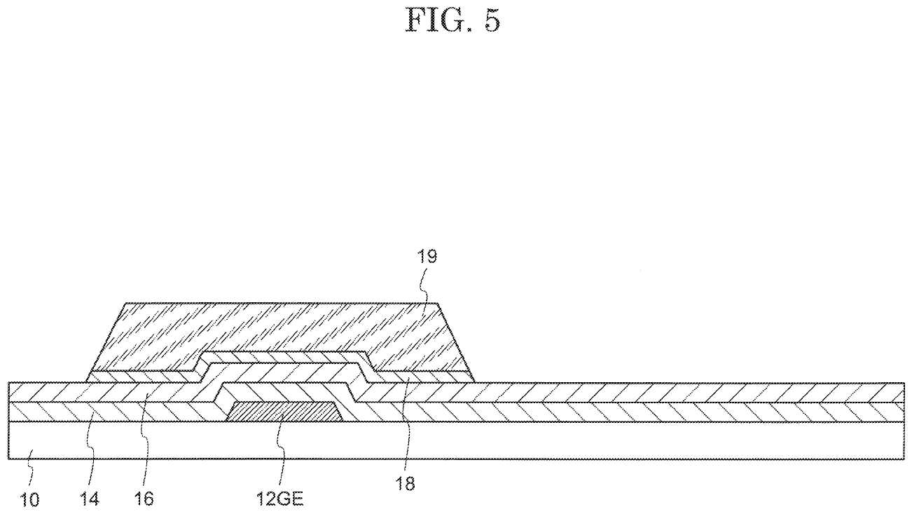

FIG. 4 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a cross-sectional view showing a method for manufacturing a semiconductor device according to an embodiment of the present invention.

FIG. 12 is a cross-sectional view showing a method for manufacturing a semiconductor device according to an embodiment of the present invention.

FIG. 13 is a cross-sectional view showing a method for manufacturing a semiconductor device according to an embodiment of the present invention.

FIG. 14 is a cross-sectional view showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing an outline of a semiconductor device according to an embodiment of the present invention.

FIG. 18 is a cross-sectional view showing an outline of a semiconductor device according to an embodiment of the present invention.

FIG. 19 is a sequence diagram showing a method for manufacturing a semiconductor device according to an embodiment of the present invention.

FIG. 20 is a sequence diagram showing a method for manufacturing a semiconductor device according to an embodiment of the present invention.

FIG. 21 is a cross-sectional view showing a method for manufacturing a semiconductor device according to an embodiment of the present invention.

FIG. 22 is a cross-sectional view showing a method for manufacturing a semiconductor device according to an embodiment of the present invention.

FIG. 23 is a cross-sectional view showing a method for manufacturing a semiconductor device according to an embodiment of the present invention.

FIG. 24 is a plan view showing an outline of a display device according to an embodiment of the present invention.

FIG. 25 is a block diagram showing a circuit configuration of a display device according to an embodiment of the present invention.

FIG. 26 is a circuit diagram showing a pixel circuit of a display device according to an embodiment of the present invention.

FIG. 27 is a circuit diagram showing a pixel circuit of a display device according to an embodiment of the present invention.

### DESCRIPTION OF EMBODIMENTS

In order to increase the level of integration of a semiconductor device, a transistor in which crystalline silicon is used for a channel and a transistor in which an oxide semiconductor is used for a channel may be formed above the same substrate. The transistor in which the oxide semiconductor is used as the channel is often stacked above the transistor in which crystalline silicon is used as the channel. However, the transistor in which crystalline silicon is used as the channel and the transistor in which the oxide semiconductor is used as the channel have different manufacturing processes, which increases the manufacturing cost.

An embodiment of the present invention provides a semiconductor device that can be highly integrated and has a reduced manufacturing cost.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, film thicknesses, shapes, and the like of the respective portions in comparison with the actual embodiments. However, the shown shapes are merely examples, and do not limit the interpretation of the present invention. In the present specification and the drawings, the same reference signs are given to elements similar to those described previously with respect to the existing drawings, and detailed description thereof may be omitted as appropriate.

The “semiconductor device” refers to an overall device that can function by utilizing semiconductor characteristics. The transistor and the semiconductor circuit are one form of the semiconductor device. For example, a semiconductor device of the embodiments described below may be a transistor used in an integrated circuit (Integrated Circuit: IC) or a memory circuit such as a display device or a microprocessor (Micro-Processing Unit: MPU).

The “display device” refers to a structure that displays an image using an electrooptical layer. For example, the term display device may refer to a display panel including the electrooptical layer, or may refer to a structure in which another optical member (for example, a polarizing member, a backlight, a touch panel, or the like) is attached to a display cell. The “electrooptical layer” may include a liquid crystal layer, an electroluminescent (EL) layer, an electrochromic (EC) layer, an electrophoretic layer, unless there is a technical inconsistency. Therefore, although an embodiment to be described later will be described by exemplifying a liquid crystal display device including a liquid crystal layer and an organic EL display device including an organic EL layer as a display device, the structure of the present embodiment can be applied to a display device including another electrooptical layer described above.

In each embodiment of the present invention, a direction from the substrate toward the oxide semiconductor layer is referred to as “above” or “upper”. Conversely, a direction from the oxide semiconductor layer toward the substrate is referred to as “below” or “lower”. As described above, although the term “above” or “below” will be used for description for convenience of explanation, for example, an upper and lower relationship between the substrate and the oxide semiconductor layer may be arranged so as to be opposite to that shown in the drawings. In the following description, for example, the expression “oxide semiconductor layer above the substrate” merely describes the vertical relationship between the substrate and the oxide semiconductor layer as described above, and other members may be arranged between the substrate and the oxide semiconductor layer. “Above” or “below” means a stacking order in a structure in which a plurality of layers is stacked, and in the case where the stacking order is expressed as a pixel electrode above the transistor, the positional relationship may be such that the transistor and the pixel electrode do not overlap each other in a plan view. On the other hand, the expression “pixel electrode vertically above the transistor” means a positional relationship in which the transistor and the pixel electrode overlap in a plan view. In addition, “in a plan view” means viewing from a direction perpendicular to a surface of the substrate.

As used herein, the terms “film” and “layer” can optionally be interchanged with one another. Further, in this specification and the like, a plurality of oxide semiconductor layers formed from an oxide semiconductor film may be distinguished using “−1” and “−2”. In addition, a plurality of conductive layers and electrodes formed of a conductive film may be described in the same manner.

In this specification and the like, ordinal numbers are used to distinguish units, members, parts, positions, directions, and the like, and do not indicate order or priority.

In this specification and the like, the expression “a includes A, B, or C,” “a includes any of A, B or C,” “a includes one selected from the group consisting of A, B and C,” and the like does not exclude cases where a includes a plurality of combinations of A to C unless otherwise specified. Furthermore, these expressions do not exclude the case where a includes other elements.

In addition, the following embodiments can be combined with each other as long as there is no technical inconsistency.

### First Embodiment

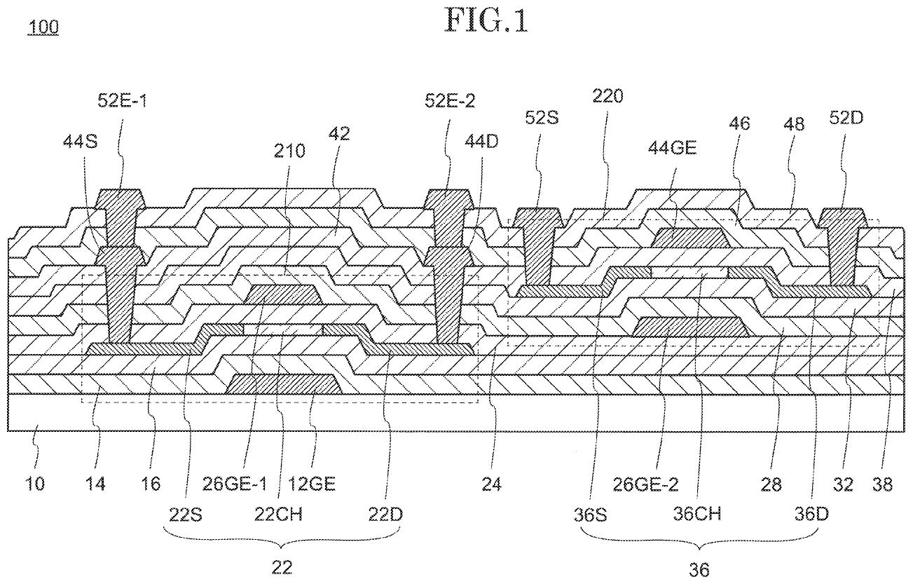

A semiconductor device 100 according to an embodiment of the present invention will be described with reference to FIG. 1 to FIG. 16.

### Configuration of Semiconductor Device 100

FIG. 1 is a cross-sectional view showing an outline of the semiconductor device 100 according to an embodiment of the present invention.

As shown in FIG. 1, the semiconductor device 100 includes a first transistor 210 and a second transistor 220 arranged above a substrate 10. The first transistor 210 includes a first gate electrode 12GE, first insulating films 14 and 16, a first oxide semiconductor layer 22, a second insulating film 24, and a second gate electrode 26GE-1. The first oxide semiconductor layer 22 includes a first channel region 22CH, a first source region 22S, and a first drain region 22D. The second transistor 220 includes a third gate electrode 26GE-2, third insulating films 28 and 32, a second oxide semiconductor layer 36, a fourth insulating film 38, and a fourth gate electrode 44GE. The second oxide semiconductor layer 36 includes a second channel region 36CH, a second source region 36S, and a second drain region 36D. In addition, in the case where the first oxide semiconductor layer 22 and the second oxide semiconductor layer 36 are not distinguished from each other, they may be simply referred to as a channel region CH, a source region S, and a drain region D.

The second transistor 220 is arranged above the first transistor 210. The second transistor 220 is arranged above the first transistor 210, which means that the second oxide semiconductor layer 36 is arranged above the first oxide semiconductor layer 22.

The first insulating films 14 and 16 function as a first gate insulating film of the first transistor 210. The second insulating film 24 functions as a second gate insulating film of the first transistor 210. The first insulating films 14 and 16 and the second insulating film 24 also function as a base film of the second transistor 220. The third insulating films 28 and 32 function as a third gate insulating film of the second transistor 220. The fourth insulating film 38 functions as a fourth gate insulating film of the second transistor. The third insulating films 28 and 32 and the fourth insulating film 38 function as an interlayer insulating film of the first transistor 210.

A first source electrode 44S and a first drain electrode 44D are arranged above the fourth insulating film 38. The first source electrode 44S and the first drain electrode 44D are connected to the first oxide semiconductor layer 22 via contact holes arranged in the second insulating film 24 to the fourth insulating film 38. The first source electrode 44S and the first drain electrode 44D are arranged above the same fourth insulating film 38 as the fourth gate electrode 44GE. The third insulating films 28 and 32 may function as an interlayer insulating film of the first transistor 210 and may function as the third gate insulating film of the second transistor 220. Fifth insulating films 46 and 48 are arranged above the first source electrode 44S, the first drain electrode 44D, and the fourth gate electrode 44GE.

A second source electrode 52S and a second drain electrode 52D are arranged above the fifth insulating film 48. The second source electrode 52S and the second drain electrode 52D are connected to the second oxide semiconductor layer 36 via contact holes arranged in the fourth insulating film 38 and the fifth insulating films 46 and 48. A first electrode 52E-1 and a second electrode 52E-2 are arranged above the fifth insulating film 48. The first electrode 52E-1 and the second electrode 52E-2 are connected to the first source electrode 44S and the first drain electrode 44D via contact holes arranged in the fifth insulating films 46 and 48.

In the present embodiment, the first transistor 210 and the second transistor 220 have the same structure. Therefore, in the configuration of the second transistor 220, description of the same structure as that of the first transistor 210 may be omitted as appropriate.

The first oxide semiconductor layer 22 and the second oxide semiconductor layer 36 have a polycrystalline structure including a plurality of crystal grains. As will be described later, the first oxide semiconductor layer 22 and the second oxide semiconductor layer 36 having a polycrystalline structure can be formed using a Poly-OS (Poly-crystalline Oxide Semiconductor) technique. Although the configurations of the first oxide semiconductor layer 22 and the second oxide semiconductor layer 36 will be described below, an oxide semiconductor having a polycrystalline structure may be referred to as Poly-OS.

The first oxide semiconductor layer 22 and the second oxide semiconductor layer 36 contain two or more metals including indium, and a ratio of indium in the two or more metals is 50% or more. As the metallic element other than indium, gallium (Ga), zinc (Zn), aluminum (AI), hafnium (Hf), yttrium (Y), zirconium (Zr), and lanthanoid-based elements are used. However, the first oxide semiconductor layer 22 and the second oxide semiconductor layer 36 may contain Poly-OS, and may contain metallic elements other than the metallic elements described above. The second oxide semiconductor layer 36 is preferably formed using an oxide semiconductor target having the same composition as that of the first oxide semiconductor layer 22. Accordingly, a manufacturing cost of the semiconductor device 100 can be reduced.

A crystal grain size of crystal grains included in Poly-OS observed from an upper surface of the first oxide semiconductor layer 22 and the second oxide semiconductor layer 36 (or a thickness direction of the first oxide semiconductor layer 22 and the second oxide semiconductor layer 36) or cross sections of the first oxide semiconductor layer 22 and the second oxide semiconductor layer 36 is 0.1 μm or more, preferably 0.3 μm or more, and more preferably 0.5 μm or more. For example, the crystal grain size of the crystal grains can be obtained by a cross-sectional SEM observation, a cross-sectional TEM observation, or an electron-beam backscattered diffraction (Electron Back Scattered Diffraction: EBSD) method.

The thickness of each of the first oxide semiconductor layer 22 and the second oxide semiconductor layer 36 is 10 nm or more and 30 nm or less. As described above, since the crystal grain size of the crystal grains included in Poly-OS is 0.1 μm or more, the first oxide semiconductor layer 22 and the second oxide semiconductor layer 36 include regions including only one crystal grain in the film thickness direction. In addition, each of the first oxide semiconductor layer 22 and the second oxide semiconductor layer 36 may have the same film thickness or different film thicknesses.

In Poly-OS, the plurality of crystal grains may have one type of crystal structure, or may have a plurality of types of crystal structures. A crystal structure of Poly-OS can be identified using an electronic wire folding method or a XRD method, or the like. That is, the crystal structure of the first oxide semiconductor layer 22 and the second oxide semiconductor layer 36 can be specified by using the electronic wire folding method, the XRD method, or the like.

The crystal structure of the first oxide semiconductor layer 22 and the second oxide semiconductor layer 36 is preferably cubic crystal. A cubic crystal has a highly symmetrical crystal structure, and even if an oxygen defect is generated in the first oxide semiconductor layer 22 and the second oxide semiconductor layer 36, the structure relaxation is unlikely to occur and the crystal structure is stable. As described above, the crystal structure of each of the plurality of crystal grains is controlled by increasing the ratio of the indium element, and the first oxide semiconductor layer 22 and the second oxide semiconductor layer 36 having a cubic crystal structure can be formed.

The first oxide semiconductor layer 22 includes a first region overlapping the second gate electrode 26GE-1 and having a first crystal structure, and a second region not overlapping the second gate electrode 26GE-1 and having a second crystal structure. Here, the first region corresponds to the first channel region 22CH. In addition, the second region corresponds to the first source region 22S and the first drain region 22D. The electrical conductivity of the second region is greater than the electrical conductivity of the first region.

The second oxide semiconductor layer 36 includes a third region overlapping the fourth gate electrode 44GE and having the first crystal structure and a fourth region not overlapping the fourth gate electrode 44GE and having the second crystal structure. Here, the third region corresponds to the second channel region 36CH. In addition, the fourth region corresponds to the second source region 36S and the second drain region 36D. The electrical conductivity of the fourth region is greater than the electrical conductivity of the third region.

The second crystal structure is the same as the first crystal structure. Here, the two crystal structures are the same means that crystal systems are the same. For example, when the crystal structure of the first oxide semiconductor layer 22 is cubic, the first crystal structure of the first region and the second crystal structure of the second region are both cubic and identical. For example, the first crystal structure and the second crystal structure can be identified by a microelectron diffraction method.

In addition, in a predetermined crystal orientation, an interplanar distance d value of the first crystal structure and an interplanar distance d value of the second crystal structure are substantially the same. Here, the two interplanar distance d values are substantially the same means that one interplanar distance d value is not less than 0.95 times and not more than 1.05 times the other interplanar distance d value. Alternatively, diffraction patterns of the first crystal structure and the second crystal structure are almost identical in the microelectron diffraction method.

There may be no grain boundaries between the first region and the second region. In addition, the first region and the second region may be included in one crystal grain. In other words, a change from the first region to the second region may be a continuous change in the crystal structure. Similarly, there may be no grain boundaries between the third region and the fourth region. In addition, the third region and the fourth region may be included in one crystal grain. In other words, a change from the third region to the fourth region may be a continuous change in the crystal structure.

The first source region 22S, the first drain region 22D, the second source region 36S, and the second drain region 36D contain the same impurity element. Further, in the first source region 22S, the first drain region 22D, the second source region 36S, and the second drain region 36D, resistivities are reduced as compared with the first channel region 22CH and the second channel region 36CH by adding an impurity element. That is, the first source region 22S, the first drain region 22D, the second source region 36S, and the second drain region 36D have physical properties as conductors. In addition, in each of the first source region 22S, the first drain region 22D, the second source region 36S, and the second drain region 36D, the same impurity element may be included in all the regions described above, or different impurity elements may be included in each layer. For example, phosphorus may be added to the first source region 22S and the first drain region 22D, and boron may be added to the second source region 36S and the second drain region 36D.

Concentrations of the impurity elements contained in the first source region 22S, the first drain region 22D, the second source region 36S, and the second drain region 36D are preferably 1×10¹⁸ cm⁻³ or more and 1×10²¹ cm⁻³ or less as measured by a SIMS spectrometry (secondary ion-mass spectrometry). Here, the impurity element means argon (Ar), phosphorus (P), or boron (B).

The impurity element is added to the first source region 22S, the first drain region 22D, the second source region 36S, and the second drain region 36D, thereby forming an oxygen defect. The first source region 22S, the first drain region 22D, the second source region 36S, and the second drain region 36D can have a lower resistance than the resistance of the first channel region 22CH and the second channel region 36CH. In addition, even if an impurity element is added to the first source region 22S, the first drain region 22D, the second source region 36S, and the second drain region 36D, and thus, an oxygen defect is formed, the crystal structure is maintained without being broken. Therefore, it can be said that the crystal structures of the first source region 22S, the first drain region 22D, the second source region 36S, and the second drain region 36D are the same as the crystal structures of the first channel region 22CH and the second channel region 36CH.

In the oxide semiconductor layer, if a large amount of oxygen defects is contained in the layer, hydrogen is trapped in the oxygen defects, which adversely affects the characteristics of the transistor. Therefore, it is required to reduce oxygen defects contained in the oxide semiconductor layer.

In the oxide semiconductor, the oxygen defects are less likely to be formed in a crystalline oxide semiconductor than in an amorphous oxide semiconductor. In addition, it is known that a crystalline oxide semiconductor is easily obtained by relatively increasing a ratio of indium contained in the oxide semiconductor. However, even if the crystalline oxide semiconductor is obtained by making the ratio of indium relatively high, there are more oxygen defects than necessary. The oxygen defects can be repaired by being supplied with oxygen. Therefore, it is necessary to repair the oxygen defects in the oxide semiconductor layer by arranging an insulating film capable of releasing oxygen as an insulating film around the oxide semiconductor layer.

On the other hand, if more oxygen is supplied to the oxide semiconductor layer than necessary, a defect level different from the oxygen defects is formed by excess oxygen contained in the oxide semiconductor layer. This may cause a phenomenon such as a characteristic variation due to a reliability test, a decrease in field-effect mobility, or a variation in characteristics.

According to the semiconductor device 100 of the embodiment, the first oxide semiconductor layer 22 and the second oxide semiconductor layer 36 include Poly-OS. As a result, the first oxide semiconductor layer 22 and the second oxide semiconductor layer 36 have high crystallinity and sufficiently reduced oxygen defects.

In addition, the first oxide semiconductor layer 22 and the second oxide semiconductor layer 36 can sufficiently reduce resistivity of the source region S and the drain region D because not only the channel region CH but also the source region S and the drain region D have a crystalline structure. Therefore, parasitic resistance of the source region S and the drain region D are reduced, and variations in the on-state current in electrical characteristics of the first transistor 210 and the second transistor 220 can be suppressed. Since mobility of the first transistor 210 and mobility of the second transistor 220 are large, in the case where the semiconductor device 100 is used in a display device or the like, the variation is suppressed and the performance is improved.

In the semiconductor device 100 according to an embodiment of the present disclosure, a channel length L of the channel region CH of the first transistor 210 and the second transistor 220 may be 2 μm or more and 4 μm or less, and a channel width of the channel region CH may be 2 μm or more and 25 μm or less, and the mobility may be 30 cm²/Vs or more, 35 cm²/Vs or more, or 40 cm²/Vs or more. The mobility in the present specification and the like means a field-effect mobility in a saturated region of a transistor, and means a maximal value of the field-effect mobility in a region where a potential difference (Vd) between a source electrode and a drain electrode is larger than a value (Vg−Vth) obtained by subtracting a threshold voltage (Vth) of the transistor from a voltage (Vg) supplied to the gate electrode.

In addition, the oxygen defects included in the channel regions CH of the first oxide semiconductor layer 22 and the second oxide semiconductor layer 36 are sufficiently reduced, so that it is possible to prevent hydrogen from being trapped in the oxygen defects. As a result, the characteristic variation in the reliability test of the first transistor 210 and the second transistor 220 can be reduced, and thus reliability of the semiconductor device can be improved.

Here, the reliability test means, for example, a NGBT (Negative Gate Bias-Temperature) stress test that applies a negative voltage to the gate, or a PGBT (Positive Gate Bias-Temperature) stress test that applies a positive voltage to the gate. In addition, BT stress tests such as NGBT and PGBT are a kind of accelerated test, and it is possible to evaluate a change in the properties (aging) of the transistor caused by long-term use in a short time. In particular, a variation of the threshold voltage of the transistor before and after the BT stress test is a key indicator for examining the reliability. It can be said that the transistor has higher reliability as the variation of the threshold voltage decreases before and after the BT stress test.

In addition, in the case where two transistors having different semiconductor materials are stacked, a wiring structure for connecting the two transistors becomes complicated. In addition, in a process of manufacturing the semiconductor device, a constituent material of the lower transistor may adversely affect a constituent material of the upper transistor. For example, a transistor using low-temperature polysilicon is formed in a lower layer than a transistor using an oxide semiconductor because it is necessary to perform a laser irradiation process on amorphous silicon. As a constituent material of the transistor using low-temperature polysilicon, a material containing a large amount of hydrogen is used. This hydrogen is likely to adversely affect the oxide semiconductor. Therefore, in the case where the transistor using low-temperature polysilicon and the transistor using the oxide semiconductor are formed so as to overlap each other, an insulating layer may be increased or a heat treatment may be increased in order to reduce an influence of hydrogen emitted from the constituent material of the transistor using low-temperature polysilicon. Further, even if both the transistor using crystalline silicon and the transistor using the oxide semiconductor have the same top-gate structure, structures and film thicknesses of the insulating material and the conductive material used in the transistor using crystalline silicon and the transistor using the oxide semiconductor are different from each other, so that the structure of the transistor cannot be shared.

Since high mobility can be obtained in both the first transistor 210 and the second transistor 220, a transistor in which an oxide semiconductor is used as a channel can be used as a transistor in which high-speed driving is required. As a result, it is not necessary to form a transistor in which crystalline silicon is used for a channel as a transistor requiring high-speed driving. Therefore, it is not necessary to separate the transistors that require high-speed driving from the transistors that require other characteristics.

Further, in the semiconductor device 100 according to an embodiment of the present invention, since two transistors having the same semiconductor material are stacked, the wiring structure for connecting two transistors can be simplified. In addition, it is easy to make the structures of the first transistor 210 and the second transistor 220 using the oxide semiconductor common to each other. For example, the first transistor 210 and the second transistor 220 may have a dual-gate structure with an oxide semiconductor layer interposed therebetween. In addition, the conductive material used as the gate electrode of the first transistor 210 and the second transistor 220 and an insulating material used as a gate insulating film can have the same structure.

In the present embodiment, the first transistor 210 includes the first gate electrode 12GE, a stack of a silicon nitride film and a silicon oxide film as the first insulating films 14 and 16, the first oxide semiconductor layer 22, a silicon oxide film as the second insulating film 24, and the second gate electrode 26GE-1. Similarly, the second transistor includes the third gate electrode 26GE-2, a stack of a silicon nitride film and a silicon oxide film as the third insulating films 28 and 32, the second oxide semiconductor layer 36, a silicon oxide film as the fourth insulating film 38, and the fourth gate electrode 44GE. That is, the first gate electrode 12GE and the third gate electrode 26GE-2, the first insulating films 14 and 16 and the third insulating films 28 and 32, the second insulating film 24 and the fourth insulating film 38, and the second gate electrode 26GE-1 and the fourth gate electrode 44GE correspond to each other. Further, the first oxide semiconductor layer 22 and the second oxide semiconductor layer 36 have a polycrystalline structure. Therefore, the second transistor 220 can be stacked on the first transistor 210 having the same performance.

In the present embodiment, a top-gate transistor that drives the transistor by the second gate electrode 26GE-1 is used as the first transistor 210. As the second transistor 220, a top-gate transistor that drives the transistor by the fourth gate electrode 44GE is used. Therefore, a thickness of the second insulating film 24 is preferably smaller than a thickness of the first insulating films 14 and 16. Similarly, a thickness of the fourth insulating film 38 is preferably smaller than the thicknesses of the third insulating films 28 and 32.

For example, in the case where a semiconductor device is applied to an organic EL display, six or more driving transistors and switching transistors may be required in a single pixel. In the case where six transistors are arranged in the same plane, an area of six transistors is required. Therefore, in the case where the pixel is made to have high definition, it is difficult to further integrate the pixel circuit.

In the semiconductor device 100, transistors having the same function can be arranged in a stacked manner. For example, an area of the pixel circuit can be reduced by arranging the switching transistors in the pixel circuit in a stacked manner in an upper layer and the lower layer. As a result, a region occupied by the pixel circuit can be reduced, so that a higher-definition organic EL display can be arranged.

Each of the first transistor 210 and the second transistor 220 has high mobility. Therefore, it is also suitable for a driving circuit that requires high-speed driving. Further, in the case where the semiconductor device 100 is applied to a driving circuit of a display device, the first transistor 210 in the lower layer and the second transistor 220 in the upper layer can be arranged so as to be close to each other or partially or entirely overlapping each other. Further, the wiring of the lower first transistor 210 can be extended under the upper second transistor 220. Accordingly, an area of the drive circuit of the display device can be reduced. Thus, it is possible to provide a display device having a narrow frame.

In the present embodiment, although a configuration is exemplified in which a top-gate transistor that drives the transistor by the second gate electrode 26GE-1 is used as the first transistor 210, the configuration is not limited to this configuration. For example, a bottom-gate transistor that drives the transistor by the first gate electrode 12GE may be used as the first transistor 210. Alternatively, a dual-gate transistor that drives the transistor by the first gate electrode 12GE and the second gate electrode 26GE-1 may be used as the first transistor 210. The second transistor 220 is also similar to the first transistor 210. The second transistor 220 is not limited to the top-gate transistor, and may be either the bottom-gate transistor or the dual-gate transistor. The configuration described above is merely an embodiment, and the present invention is not limited to the above configuration.

The first gate electrode 12GE functions as a light shielding film for the bottom-gate of the first transistor 210 and the first oxide semiconductor layer 22. The first insulating films 14 and 16 and the second insulating film 24 have a function of releasing oxygen by a heat treatment in a manufacturing process. The second insulating film 24, the third insulating films 28 and 32, and the fourth insulating film 38 have a function of insulating the first gate electrode 12GE, the first source electrode 44S, and the first drain electrode 44D, and reducing parasitic capacitance therebetween. An operation of the first transistor 210 is mainly controlled by the voltage supplied to the second gate electrode 26GE-1. An auxiliary voltage is supplied to the first gate electrode 12GE. In addition, the first gate electrode 12GE may be simply used as a light shielding film, and in this case, a specific voltage may not be supplied to the first gate electrode 12GE and may be floating.

The third gate electrode 26GE-2 functions as a light shielding film for the bottom-gate of the second transistor 220 and the second oxide semiconductor layer 36. The third insulating film 32 and the fourth insulating film 38 have a function of releasing oxygen by a heat treatment in the manufacturing process. The fourth insulating film 38 and the fifth insulating films 46 and 48 have a function of insulating the fourth gate electrode 44GE from the second source electrode 52S and the second drain electrode 52D and reducing parasitic capacitance therebetween. The operation of the second transistor 220 is controlled mainly by the voltage supplied to the fourth gate electrode 44GE. An auxiliary voltage is supplied to the third gate electrode 26GE-2. In addition, the third gate electrode 26GE-2 may be simply used as a light shielding film, and in this case, a particular voltage may not be supplied to the third gate electrode 26GE-2 and may be floating.

### Method for Manufacturing Semiconductor Device 100

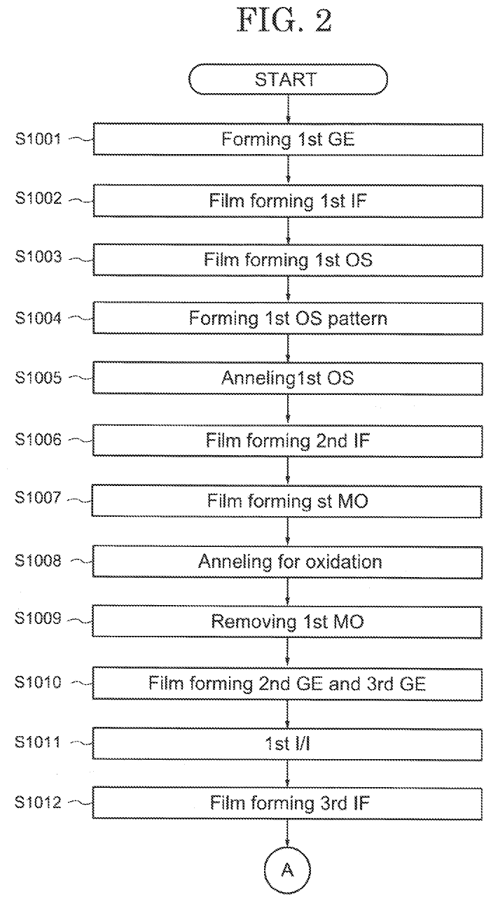

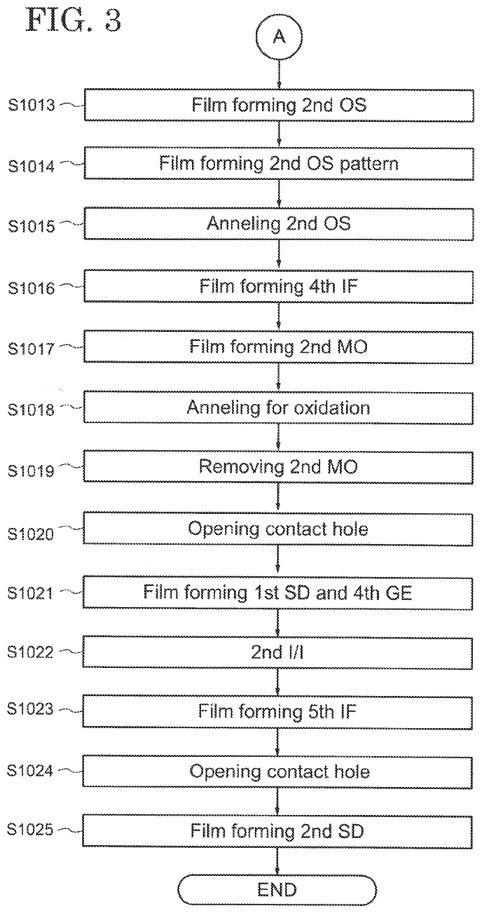

A method for manufacturing the semiconductor device 100 according to an embodiment of the present invention will be described with reference to FIG. 2 to FIG. 16. FIG. 2 and FIG. 3 are sequence diagrams showing a method for manufacturing the semiconductor device 100 according to an embodiment of the present invention.

As shown in FIG. 2 and FIG. 4, the first gate electrode 12GE is formed above the substrate 10 (“1st GE formation” in a step S1001 shown in FIG. 2).

A rigid substrate having translucency, such as a glass substrate, a quartz substrate, and a sapphire substrate, is used as the substrate 10. In the case where the substrate 10 needs to be flexible, a substrate containing a resin such as a polyimide substrate, an acrylic substrate, a siloxane substrate, or a fluororesin substrate is used as the substrate 10. In the case where a substrate containing a resin is used as the substrate 10, an impurity element may be introduced into the resin in order to improve heat resistance of the substrate 10. In particular, in the case where the semiconductor device 100 is a top emission type display, since the substrate 10 does not need to be transparent, impurities that reduce the transparency of the substrate 10 may be used. In the case where the semiconductor device 100 is used in an integrated circuit that is not a display device, a substrate that does not have a light transmitting property, such as a semiconductor substrate such as a silicon substrate, a silicon carbide substrate, a compound semiconductor substrate, or a conductive substrate such as a stainless-steel substrate, may be used as the substrate 10.

The first gate electrode 12GE is formed by processing a conductive film formed by a sputtering method. A typical metallic material is used as the first gate electrode 12GE. Examples of the first gate electrode 12GE include aluminum (AI), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and alloys or compounds thereof. As the first gate electrode 12GE, the materials described above may be used in a single layer or in a stacked layer.

As shown in FIG. 2 and FIG. 4, the first insulating films 14 and 16 are formed above the board 10 and the first gate electrode 12GE (“1st IF film formation” in a step S1002 shown in FIG. 2). The first insulating films 14 and 16 are formed by a CVD (Chemical Vapor Deposition) method or a sputtering method. A general insulating material is used as the first insulating films 14 and 16. For example, inorganic insulating materials such as silicon oxide (SiOₓ), silicon oxynitride (SiOₓN_{y}), silicon nitride (SiNₓ), and silicon nitride oxide (SiNₓO_{y}) are used as the first insulating films 14 and 16. SiOₓN_{y} described above is a silicon compound that contains a smaller proportion (x>y) of nitrogen (N) than oxygen (O). SiNₓO_{y} is a silicon compound that contains a smaller proportion (x>y) of oxygen than nitrogen.

It is preferable that the insulating material containing nitrogen and the insulating material containing oxygen are formed in this order from the substrate 10 as the first insulating films 14 and 16. For example, impurities that diffuse from the substrate 10 side toward the first oxide semiconductor layer 22 can be blocked by using the insulating material containing nitrogen as the first insulating film 14. Further, oxygen can be released by the heat treatment by using the insulating material containing oxygen as the first insulating film 16. For example, the temperature of the heat treatment in which the insulating material containing oxygen releases oxygen is 500° C. or lower, 450° C. or lower, or 400° C. or lower. That is, for example, the insulating material containing oxygen releases oxygen at the heat treatment temperature performed in the manufacturing process of the semiconductor device 100 in the case where a glass substrate is used as the substrate 10. In the present embodiment, although an example is described in which a stacked structure of silicon nitride and silicon oxide is used as the first insulating films 14 and 16, a single-layer structure of the material described above may be used as the first insulating film.

As shown in FIG. 2 and FIG. 4, a first oxide semiconductor film 17 is formed above the first insulating film 16 (“1st OS film formation” in a step S1003 shown in FIG. 2). In this process, the first oxide semiconductor film 17 may be formed above the substrate 10. The first oxide semiconductor film 17 is formed by a sputtering method or an atomic layer deposition (ALD) method. For example, a thickness of the first oxide semiconductor film 17 is more than 10 nm and 30 nm or less.

As the first oxide semiconductor film 17, a metal oxide having characteristics of a semiconductor can be used. As the first oxide semiconductor film 17, an oxide semiconductor containing two or more metals containing indium is used. A ratio of indium in the two or more metals is 50% or more. As the metal element other than indium, gallium (Ga), zinc (Zn), aluminum (AI), hafnium (Hf), yttrium (Y), zirconium (Zr), or a lanthanoid-based element is used as the first oxide semiconductor film 17.

In the case where the first oxide semiconductor film 17 is crystallized by OS annealing to be described later, the first oxide semiconductor film 17 after the film formation and prior to the OS annealing is preferably amorphous (with few crystalline components of the oxide semiconductor). That is, it is preferable that a method for manufacturing the first oxide semiconductor film 17 is in a condition in which the first oxide semiconductor film 17 immediately after the film formation does not crystallize as much as possible. For example, in the case where the first oxide semiconductor film 17 is formed by a sputtering method, the first oxide semiconductor film 17 is formed while controlling the temperature of an object to be formed (the semiconductor device 100 and the structures formed thereon).

If film formation is performed above the object to be film-formed by the sputtering method, ions generated in a plasma and the atoms recoiled by a sputtering target collide with the object to be film-formed, so that the temperature of the object to be film-formed increases with the film forming process. When the temperature of the object to be formed during the film forming process increases, microcrystals are contained in the first oxide semiconductor film 17 in a state immediately after the film formation. If the first oxide semiconductor film 17 contains microcrystals, a grain size cannot be increased by subsequent OS annealing. For example, the film formation can be performed while cooling the film formation target in order to control the temperature of the object to be film-formed as described above. For example, the object to be film-formed can be cooled from a surface opposite to a film-forming surface so that the temperature of the film-forming surface of the object to be film-formed (hereinafter, referred to as “film forming temperature”) is 100° C. or lower, 70° C. or lower, 50° C. or lower, or 30° C. or lower. In particular, the film forming temperature of the first oxide semiconductor film 17 of the present embodiment is preferably 50° C. or lower. It is possible to obtain the first oxide semiconductor film 17 having a small crystal component in a state immediately after the film formation by forming the first oxide semiconductor film 17 while cooling the substrate. In the present embodiment, the first oxide semiconductor film 17 is formed at the film forming temperature of 50° C. or lower, and the OS annealing described later is performed at a heating temperature of 400° C. or higher. As described above, a difference between the temperature at which the first oxide semiconductor film 17 is formed and the temperature at which the first oxide semiconductor film 17 is OS annealed is preferably 350° C. or higher in the present embodiment.

In the sputtering process, the first oxide semiconductor film 17 which is amorphous is formed under a condition of an oxygen partial pressure of 10% or less. If the oxygen partial pressure is high, microcrystals are contained in the first oxide semiconductor film 17 immediately after film formation due to excessive oxygen contained in the first oxide semiconductor film 17. Therefore, it is preferable that the first oxide semiconductor film 17 be formed under a condition where the oxygen partial pressure is low. For example, the oxygen partial pressure is 3% or more and 5% or less, and preferably 3% or more and 4% or less. In addition, in the case where the oxide semiconductor film is formed at an oxygen partial pressure of 2%, the oxide semiconductor film may not have enough crystallinity even if the OS annealing is performed later.

As shown in FIG. 2 and FIG. 5, a pattern of a first oxide semiconductor layer 18 is formed (“1st OS pattern formation” in a step S1004 shown in FIG. 2). A resist mask 19 is formed above the first oxide semiconductor film 17, and the first oxide semiconductor film 17 is etched using the resist mask 19. Wet etching may be used, or dry etching may be used as the etching of the first oxide semiconductor film 17. As the wet etching, etching can be performed using an acidic etchant. For example, oxalic acid, PAN, sulfuric acid, hydrogen peroxide solution, or hydrofluoric acid can be used as the etchant. Thus, the patterned first oxide semiconductor layer 18 can be formed. Thereafter, the resist mask 19 is removed.

The first oxide semiconductor film 17 is preferably patterned prior to the OS annealing. When the first oxide semiconductor film 17 is crystallized by the OS annealing, the first oxide semiconductor film 17 tends to be difficult to be etched. Further, even if the patterned first oxide semiconductor layer 18 is damaged by the etching, damage to the first oxide semiconductor layer 18 can be repaired by the OS annealing, which is preferable.

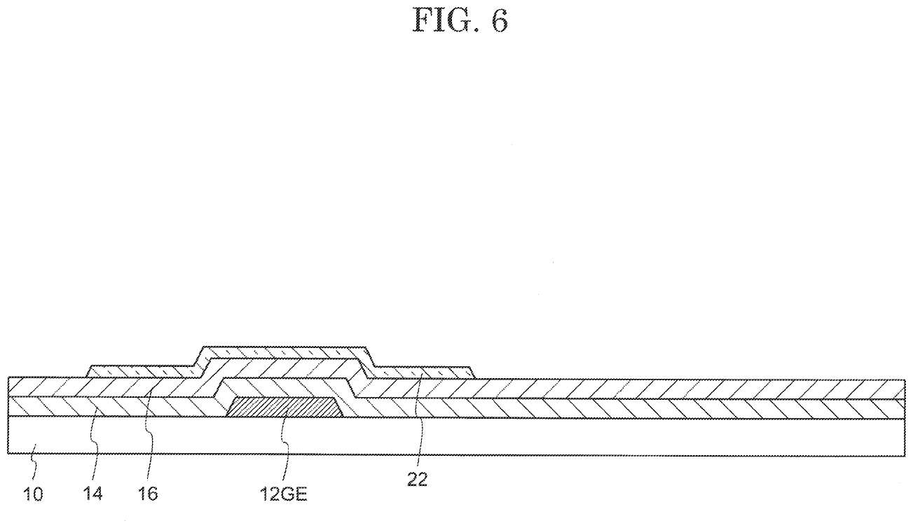

As shown in FIG. 2 and FIG. 6, the first oxide semiconductor layer 18 is subjected to the heat treatment (OS annealing) after the first oxide semiconductor layer 18 is patterned (“1st OS annealing” in a step S1005 shown in FIG. 2). In the OS annealing, the first oxide semiconductor layer 18 is held for a predetermined period of time at a predetermined arrival temperature. The predetermined arrival temperature is 300° C. or higher and 500° C. or lower, preferably 350° C. or higher and 450° C. or lower. In addition, the holding time at the arrival temperature is 15 minutes or more and 120 minutes or less, and preferably 30 minutes or more and 60 minutes or less. The first oxide semiconductor layer 18 is crystallized by performing the OS annealing, and the first oxide semiconductor layer 22 having a polycrystalline structure is formed.

In a thin film transistor, field-effect mobility tends to be increased by reducing a thickness of an oxide semiconductor layer, thereby increasing carriers in a vicinity of an interface with a gate insulating film and reducing an influence of a back channel. In other words, the thin film transistor tends to have a higher field-effect mobility as a thickness of a region functioning as a channel of the oxide semiconductor layer decreases. Therefore, the smaller the thickness of the oxide semiconductor layer, the better. However, even if a heat treatment is performed after the oxide semiconductor layer is formed to have a thickness of 10 nm or less, the oxide semiconductor layer may not have enough crystallinity.

In addition, in the thin film transistor, the crystallinity of the first oxide semiconductor layer 22 contributes to the improvement of the field-effect mobility. Therefore, the first oxide semiconductor layer 22 preferably has a polycrystalline structure. However, if microcrystals are contained in the first oxide semiconductor film 17 at the time of film formation, a crystal grain size of crystal grains having the polycrystalline structure cannot be increased even if the heat treatment is performed thereafter. Thus, it is difficult to achieve both thinning and good crystallization of the oxide semiconductor layer.

Therefore, when the first oxide semiconductor film 17 is formed by the sputtering method, the first oxide semiconductor film is formed at a low oxygen partial pressure of 3% or more and 5% or less. By forming the first oxide semiconductor film 17 under a condition in which the oxygen partial pressure is low, it is possible to prevent excessive oxygen from being contained in the first oxide semiconductor film 17, and it is possible to prevent microcrystals from being contained in the first oxide semiconductor film 17 immediately after the formation of the oxygen partial pressure. As a result, it is possible to suppress a growth of crystals from the microcrystals during the heat treatment of the first oxide semiconductor layer 18. Therefore, even in the case where the first oxide semiconductor film 17 is formed with a thin film thickness of 10 nm or more and 30 nm or less, a crystal grain size of polycrystalline grains of the first oxide semiconductor layer 22 can be increased.

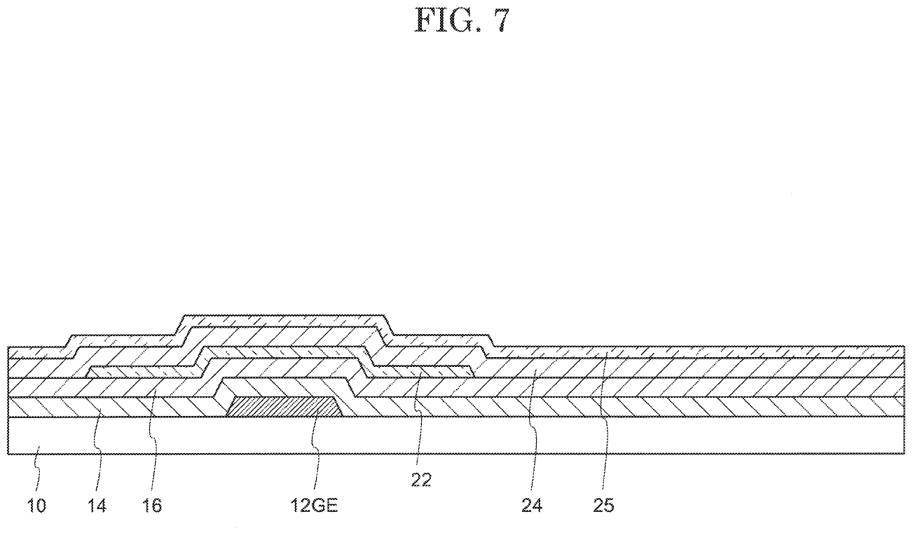

As shown in FIG. 2 and FIG. 7, the second insulating film 24 is formed above the first oxide semiconductor layer 22 (“2nd IF film formation” in a step S1006 shown in FIG. 2). A manufacturing method and an insulating material of the second insulating film 24 refer to the description of the first insulating films 14 and 16. Further, for example, the thickness of the second insulating film 24 is 50 nm or more and 300 nm or less, 60 nm or more and 200 nm or less, or 70 nm or more and 150 nm or less.

An insulating material containing oxygen is preferably used as the second insulating film 24. It is preferable to use an insulating film having few defects as the second insulating film 24. For example, in the case where a composition ratio of oxygen in the second insulating film 24 and a composition ratio of oxygen in an insulating film (hereinafter referred to as “other insulating film”) having the same composition as that of the second insulating film 24 are compared, the composition ratio of oxygen in the second insulating film 24 is closer to a stoichiometric ratio with respect to the insulating film than the composition ratio of oxygen in the other insulating film. For example, in the case where silicon oxide (SiOₓ) is used for each of the second insulating film 24 and the fifth insulating film 48, a composition ratio of oxygen in the silicon oxide used as the second insulating film 24 is closer to a stoichiometric ratio of silicon oxide than a composition ratio of oxygen in a silicon oxide used as the fifth insulating film 48. For example, a film in which no defects are observed when evaluated by electron-spin resonance (ESR) may be used as the second insulating film 24.

In order to form an insulating film having few defects as the second insulating film 24, the second insulating film 24 may be formed at a film forming temperature of 350° C. or higher. For example, the thickness of the second insulating film 24 is 50 nm or more and 300 nm or less, 60 nm or more and 200 nm or less, or 70 nm or more and 150 nm or less. After the second insulating film 24 is formed, oxygen may be implanted into a portion of the second insulating film 24. In the present embodiment, silicon oxide is formed at a film forming temperature of 350° C. or higher in order to form an insulating film with few defects as the second insulating film 24.

As shown in FIG. 2 and FIG. 7, a first metal oxide film 25 is formed above the second insulating film 24 (“1st MO film formation” in the step S1007 shown in FIG. 2). The first metal oxide film 25 is formed by sputtering. Oxygen is implanted into the second insulating film 24 by forming the first metal oxide film 25 by a sputtering method.

As the first metal oxide film 25, a metal oxide containing aluminum as a main component is used. For example, inorganic insulating layers such as aluminum oxide (AlOₓ), aluminum oxynitride (AlOₓN_{y}), aluminum nitride oxide (AlNxOy), and aluminum nitride (AlNₓ) are used as the first metal oxide film 25. The metal oxide film containing aluminum as a main component means that a ratio of aluminum contained in the metal oxide film is 1% or more of the entire first metal oxide film 25. The ratio of aluminum contained in the first metal oxide film 25 may be 5% or more and 70% or less, 10% or more and 60% or less, or 30% or more and 50% or less of the entire first metal oxide film 25. The ratio may be a mass ratio or a weight ratio.

For example, a thickness of the first metal oxide film 25 is 5 nm or more and 100 nm or less, 5 nm or more and 50 nm or less, 5 nm or more and 30 nm or less, or 7 nm or more and 15 nm or less. In the present embodiment, aluminum oxide is used as the first metal oxide film 25. Aluminum oxide has a high barrier property against gases such as oxygen or hydrogen. In the present embodiment, the aluminum oxide used as the first metal oxide film 25 suppresses the oxygen implanted into the second insulating film 24 from being diffused outward during the formation of the first metal oxide film 25. In other words, the barrier property refers to a function of suppressing a permeation of a gas such as oxygen or hydrogen through the aluminum oxide. That is, even if a gas such as oxygen is present from a layer arranged below an aluminum oxide film, the gas does not move to a layer arranged above the aluminum oxide film. Alternatively, even if a gas such as oxygen is present from the layer arranged above the aluminum oxide film, the gas does not move to the layer arranged below the aluminum oxide film.

For example, in the case where the first metal oxide film 25 is formed by the sputtering method, a process gas used for sputtering remains in the first metal oxide film 25. For example, in the case where Ar is used as the process gas for sputtering, Ar may remain in the film of the second insulating film 24. The remaining Ar can be detected by the SIMS (Secondary Ion Mass Spectrometry) spectrometry to the second insulating film 24.

With the second insulating film 24 and the first metal oxide film 25 formed above the first oxide semiconductor layer 22, a heat treatment (oxidation annealing) for supplying oxygen from the second insulating film 24 to the first oxide semiconductor layer 22 is performed (“oxidation annealing” in a step S1008 shown in FIG. 2). In a process between the formation of the first oxide semiconductor film 17 and the formation of the second insulating film 24 above the first oxide semiconductor layer 22, a large number of oxygen defects are generated above an upper surface and a side surface of the first oxide semiconductor layer 22. Oxygen released from the first insulating film 16 and the second insulating film 24 is supplied to the first oxide semiconductor layer 22 by the oxidation annealing, and the oxygen defect is repaired.

In the oxidation annealing, the oxygen implanted into the second insulating film 24 is blocked by the first metal oxide film 25, and thus is suppressed from being released into the atmosphere. Accordingly, the oxygen is efficiently supplied to the first oxide semiconductor layer 22 by the oxidation annealing, and the oxygen defect is repaired.

As shown in FIG. 2, the first metal oxide film 25 is etched (removed) (“1st MO removal” in a step S1009 shown in FIG. 2). As the etching of the first metal oxide film 25, wet etching may be used, or dry etching may be used. For example, dilute hydrofluoric acid (DHF) is used as the wet etching.

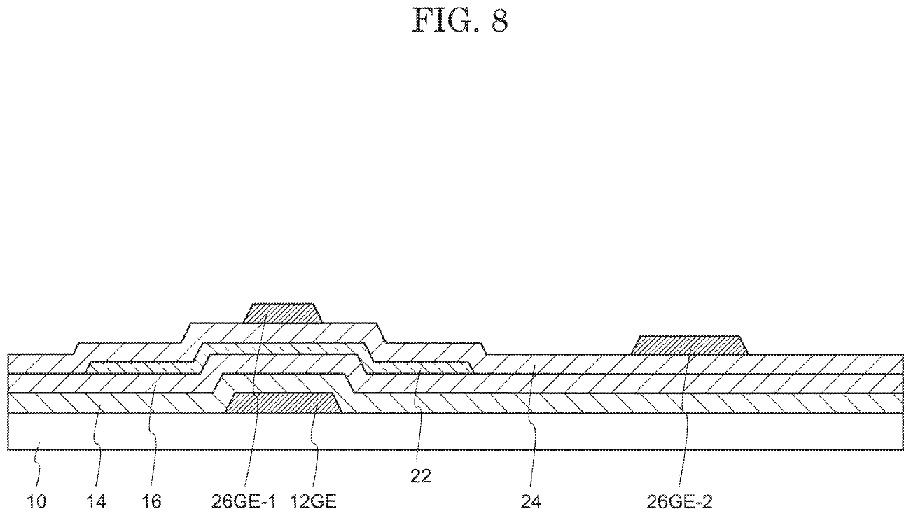

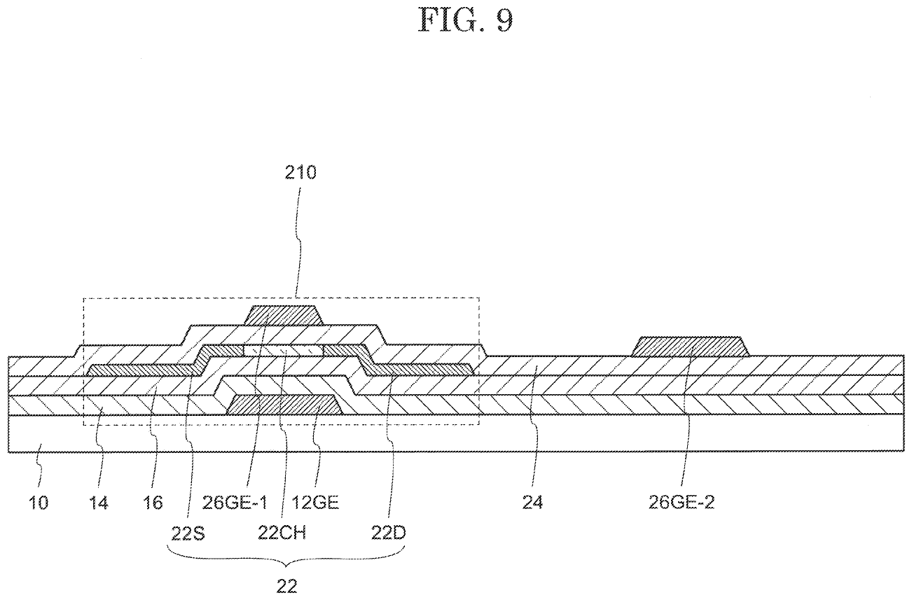

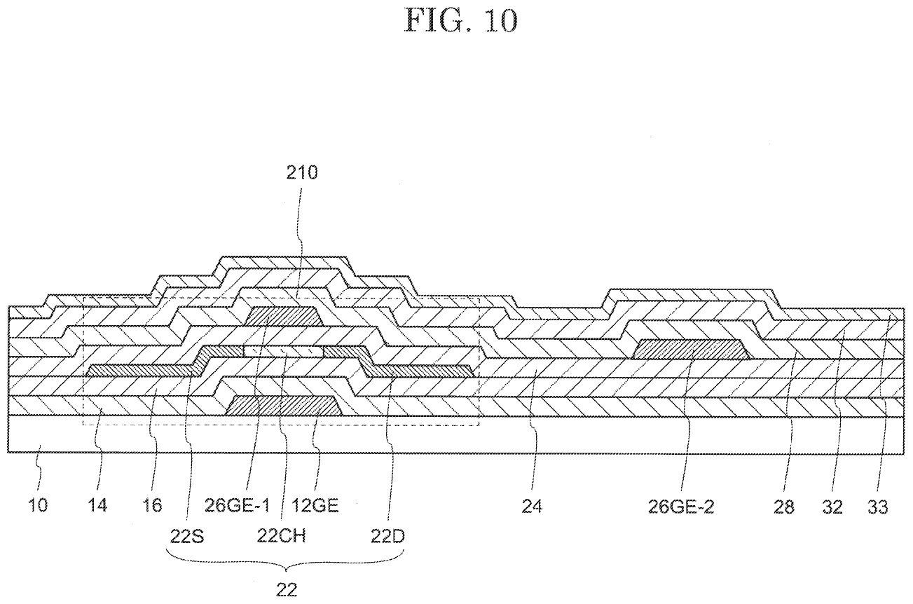

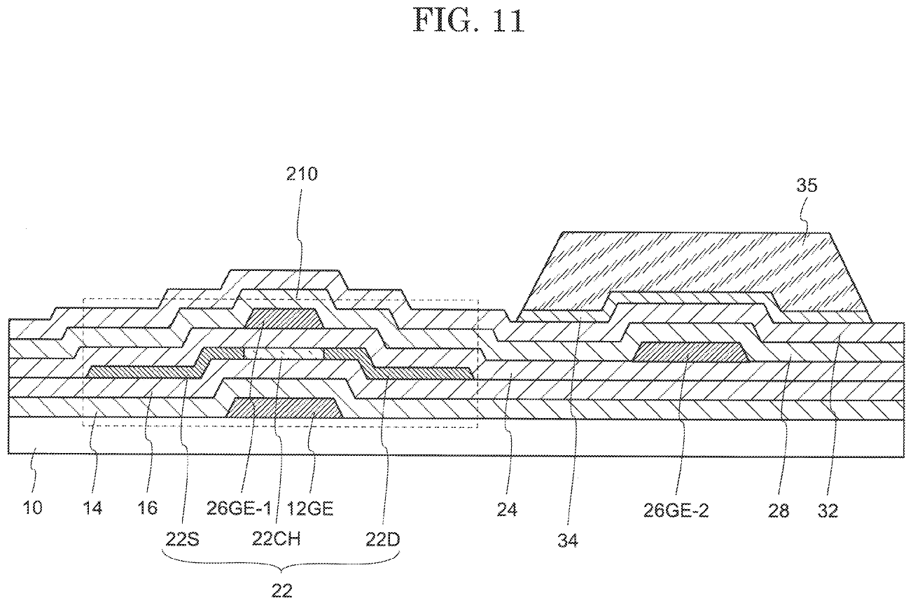

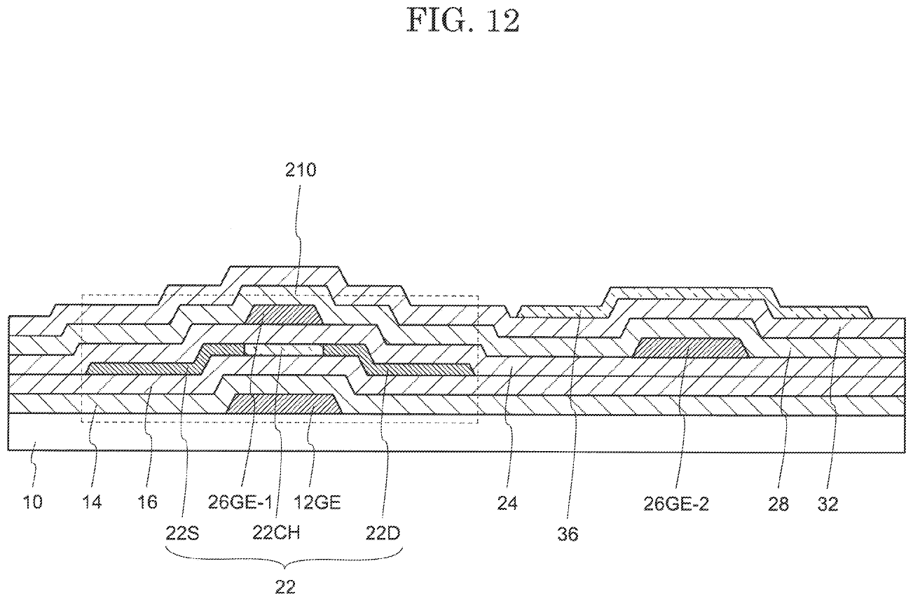

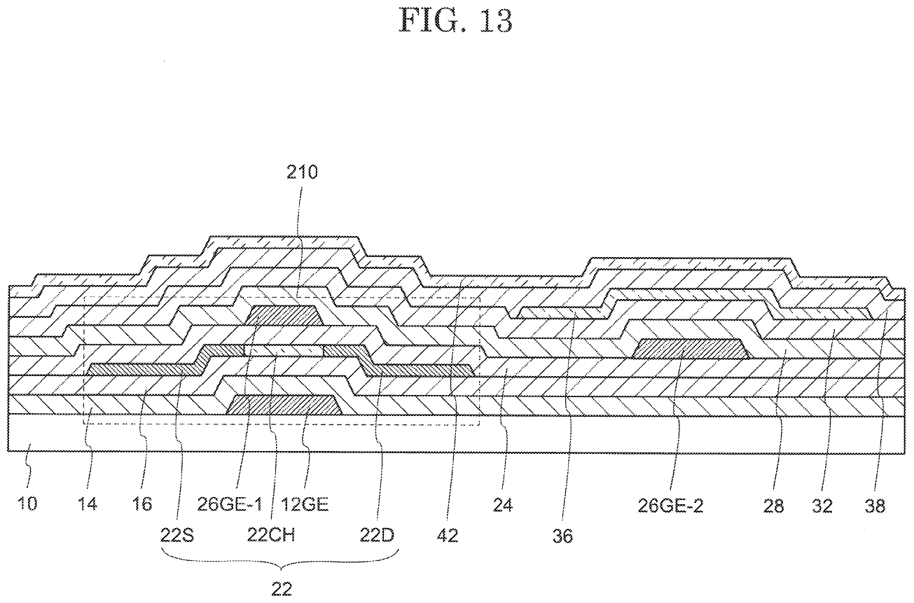

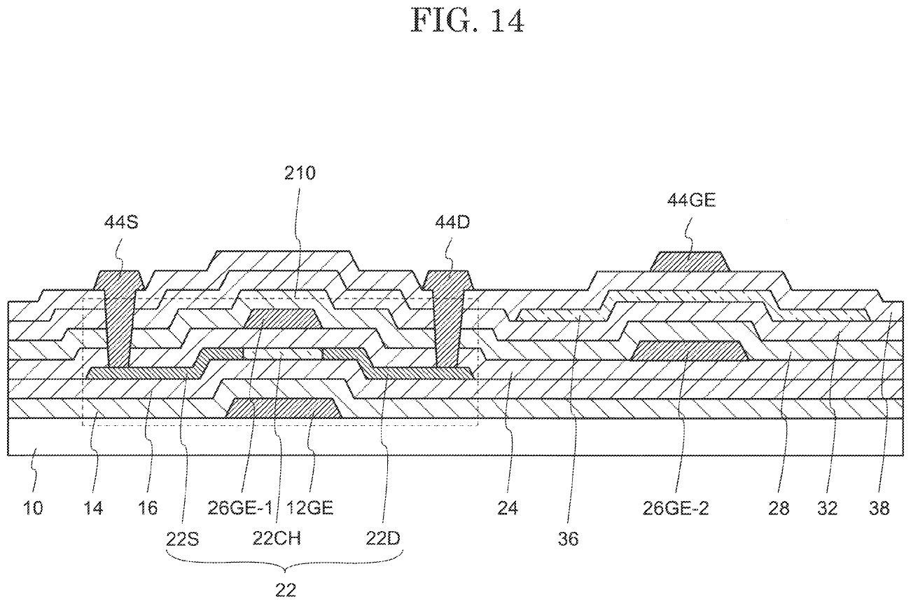

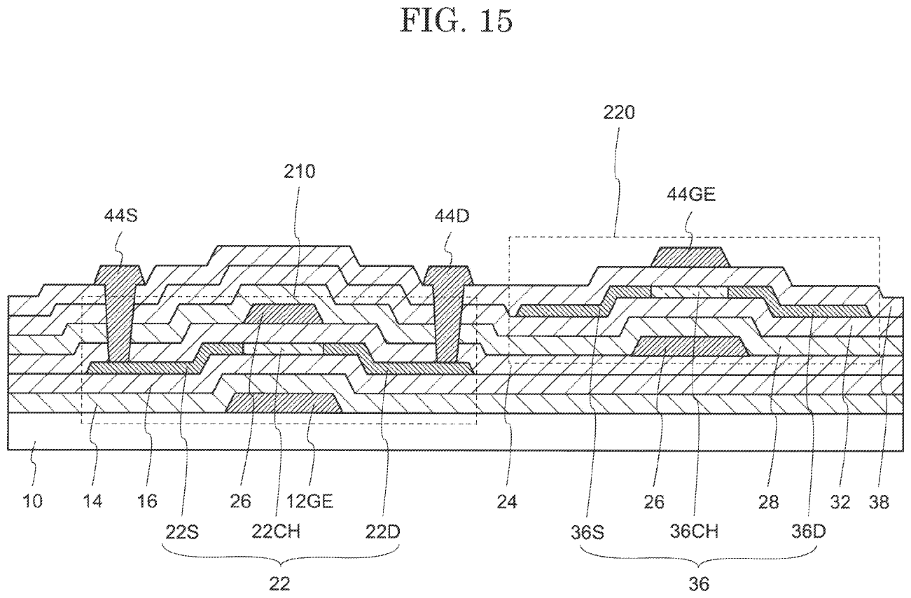

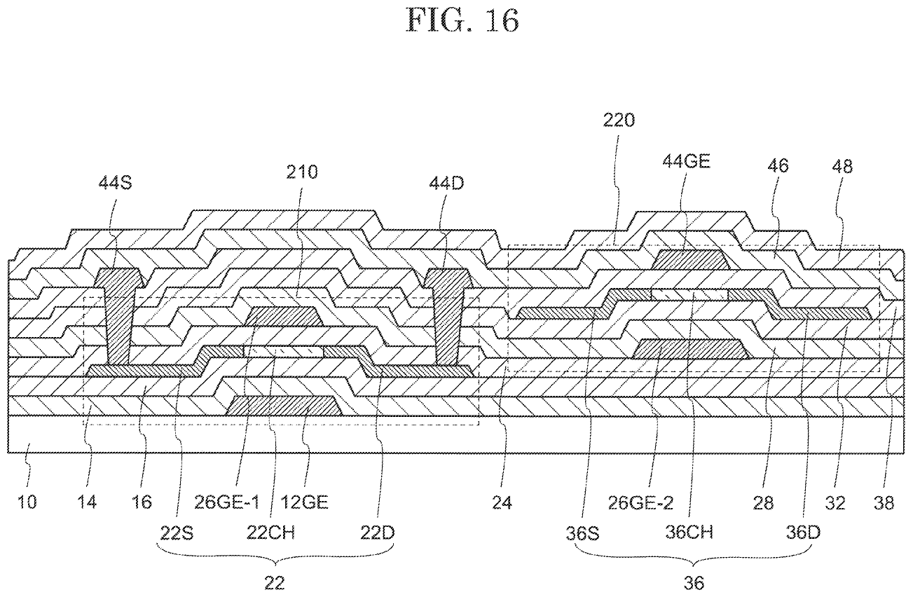

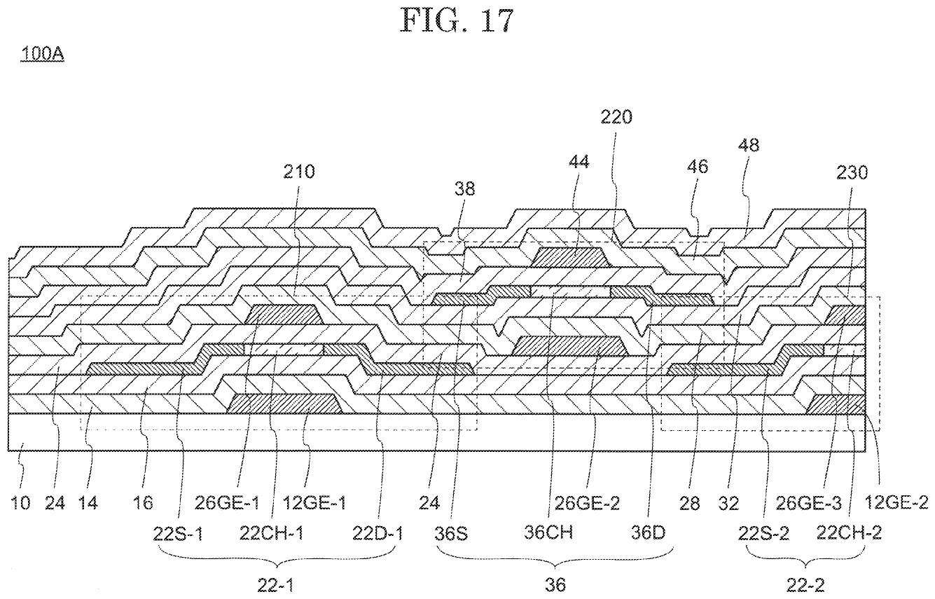

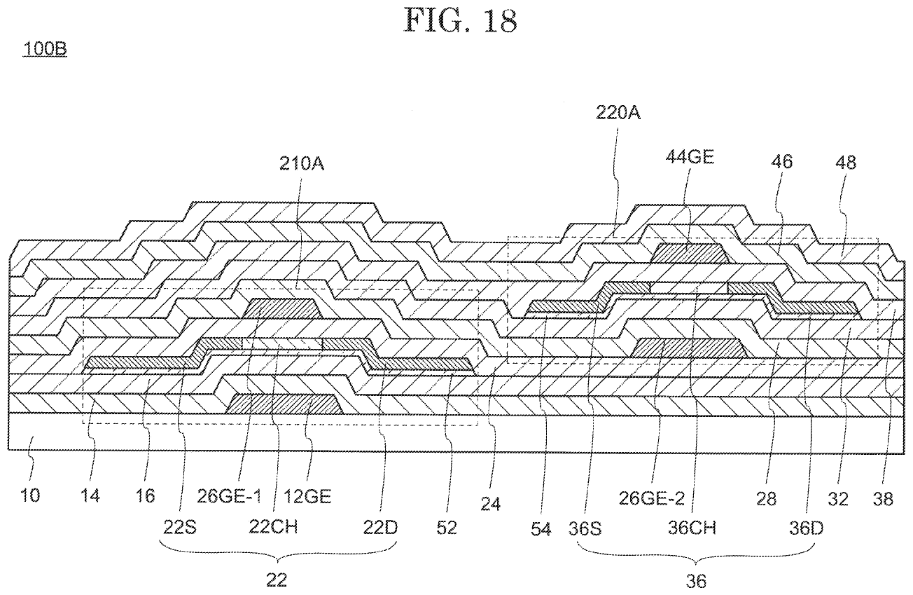

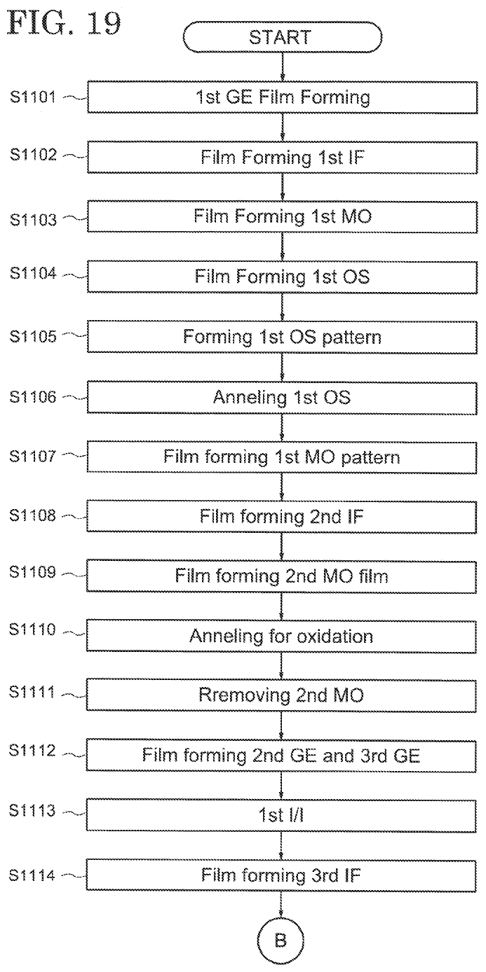

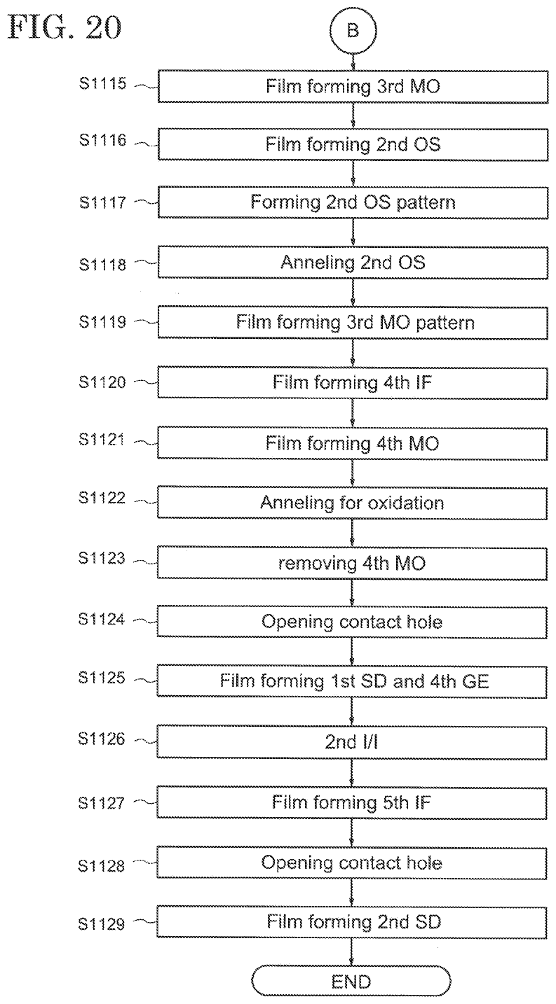

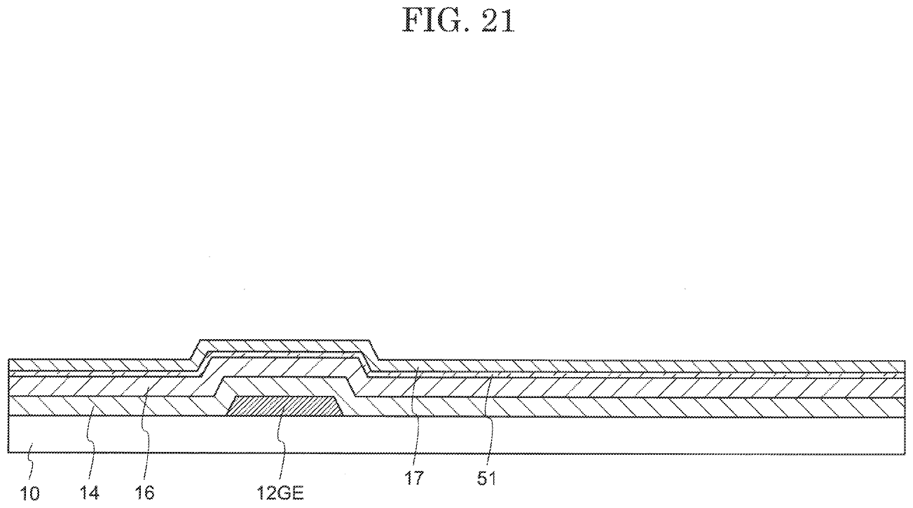

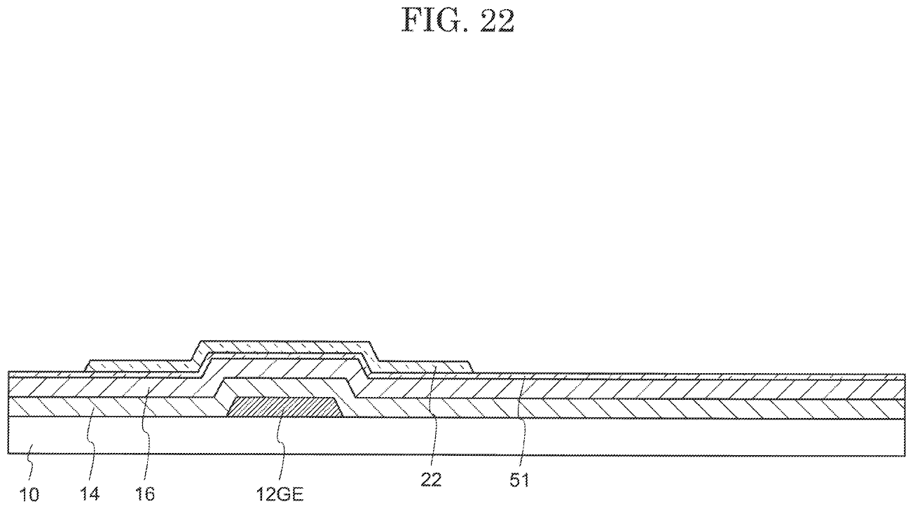

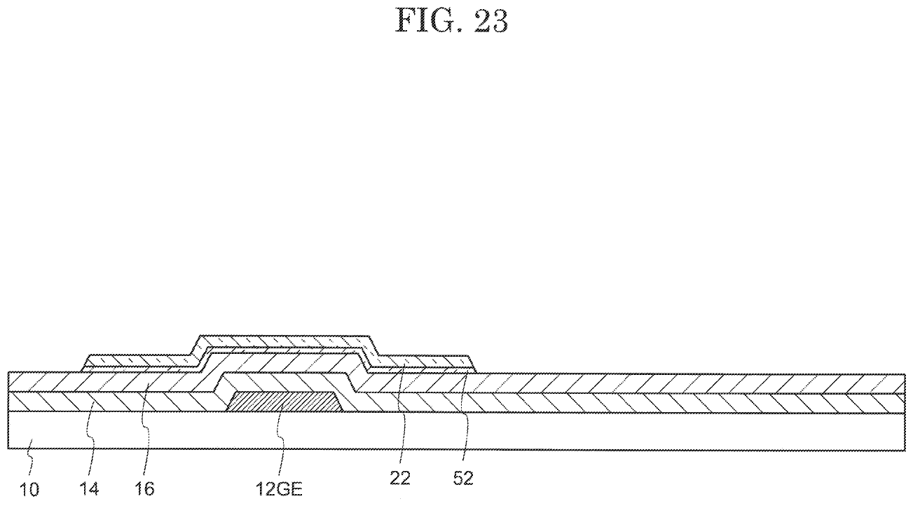

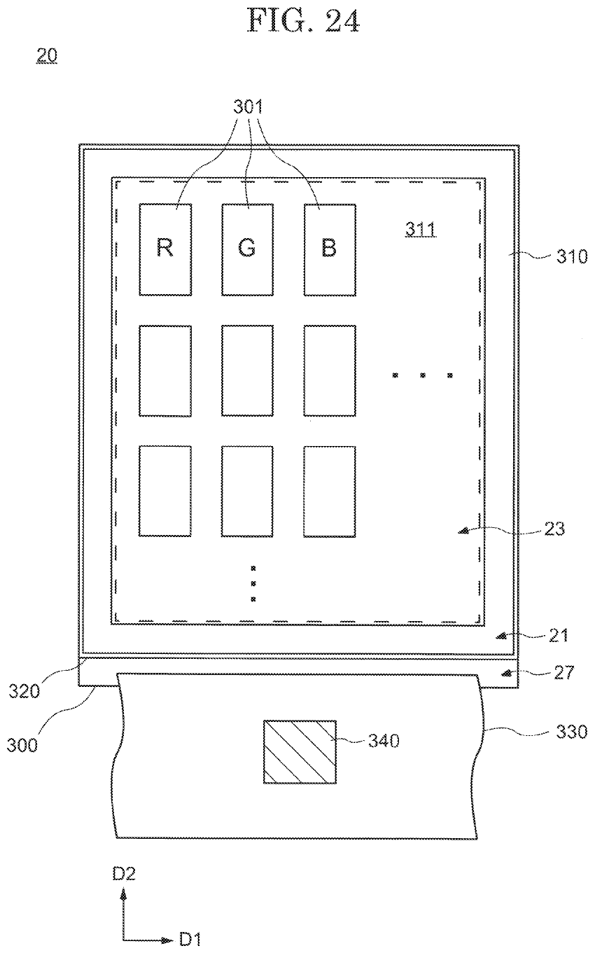

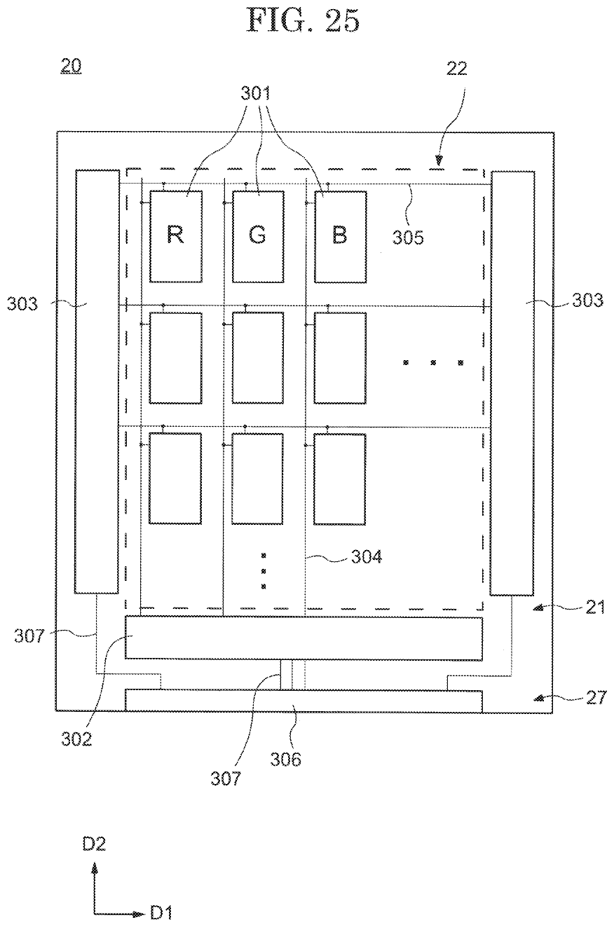

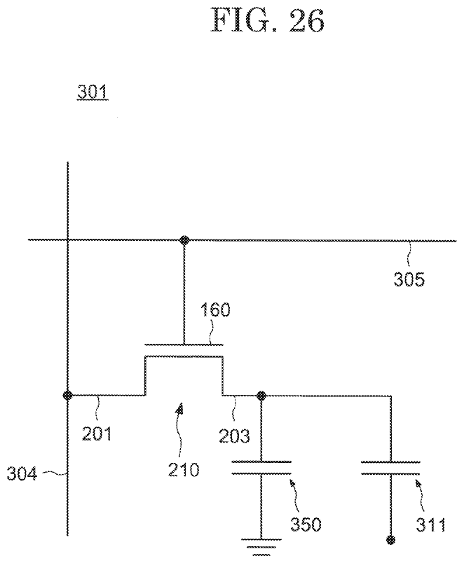

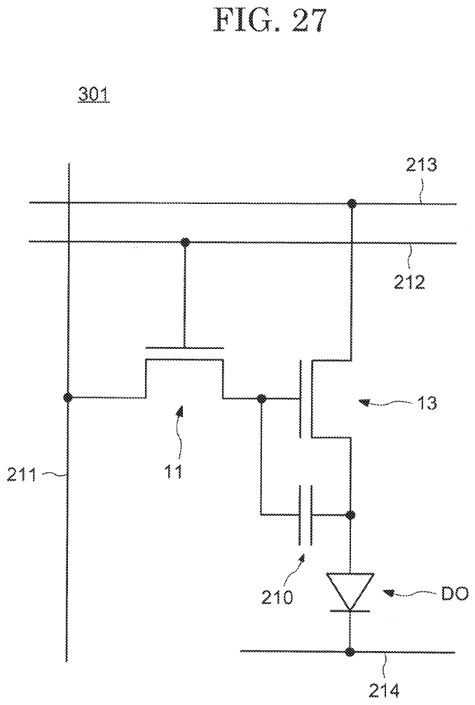

As shown in FIG. 2 and FIG. 8, the second gate electrode 26GE-1 and the third gate electrode 26GE-2 are formed above the second insulating film 24 (“2nd GE, 3rd GE formation” in a step S1010 shown in FIG. 2). The second gate electrode 26GE-1 and the third gate electrode 26GE-2 are formed by processing a conductive film formed by a sputtering method. Wirth respect to a material that can be used for the second gate electrode 26GE-1 and the third gate electrode 26GE-2, the description of the materials of the first gate electrode 12GE may be referred to. As the second gate electrode 26GE-1 and the third gate electrode 26GE-2, the materials described in the explanation of the first gate electrode 12GE may be used as a single layer or a stacked layer. The second gate electrode 26GE-1 and the third gate electrode 26GE-2 may be formed of the same material as the first gate electrode 12GE.

As shown in FIG. 2 and FIG. 9, an impurity element is added to the first oxide semiconductor layer 22 using the second gate electrode 26GE-1 as a mask (“1st I/I” in the step S1011 shown in FIG. 2). In the present embodiment, although a case is described in which the impurity element is added by an ion doping method, the impurity element may be added by ion doping.

Specifically, an impurity element is added to the first source region 22S and the first drain region 22D through the second insulating film 24 by ion-implantation. In the first oxide semiconductor layer 22, no impurity element is added to a region overlapping the second gate electrode 26GE-1, and functions as a channel region 26CH. For example, argon (Ar), phosphorus (P), or boron (B) may be used as the impurity element. Further, in the case where boron (B) is added by the ion-implantation method, an acceleration energy may be set to be 20 keV or more and 40 keV or less, and an implantation amount of boron (B) may be set to be 1×10¹⁴ cm⁻² or more and 1×10¹⁶ cm⁻² or less. In addition, the impurity element is also added to the first insulating film 16 and the second insulating film 24 in a vicinity of the third gate electrode 26GE-2. Thereafter, in order to prevent the impurity element from being added to the regions where the second oxide semiconductor layers are formed, a resist mask may be formed in the vicinity of the third gate electrode 26GE-2, and then the impurity element may be added.

Impurity elements can be added to the first source region 22S and the first drain region 22D at a concentration of 1×10¹⁸ cm⁻³ or more and 1×10²¹ cm⁻³ or less by ion-implantation. At this time, the oxide semiconductor in the first source region 22S and the first drain region 22D is doped with an impurity element, thereby forming an oxygen defect. Hydrogen is easily trapped in the oxygen defect. Accordingly, resistivities of the first source region 22S and the first drain region 22D can be reduced to function as conductors. Even if the impurity element is added to the first oxide semiconductor layer 22 to form the oxygen defect, the crystal structure is maintained without being broken. Therefore, it can be said that the crystal structures of the first source region 22S and the first drain region 22D are the same as the crystal structure of the first channel region 22CH.

For example, in the case where an IGZO oxide semiconducting layer is used, resistance of the oxide semiconducting layer is large, so that the resistance of the source region and the drain region cannot be sufficiently reduced unless the film thickness is increased. On the other hand, in the first oxide semiconductor layer 22 having the polycrystalline structure in which the ratio of the indium element in the two or more metals is 50% or more, the sheet resistance of the first source region 22S and the first drain region 22D is 1000 Ω/sq. or less, preferably 500 Ω/sq. or less, and more preferably 250 Ω/sq. or less by adding the impurity element to the first source region 22S and the first drain region 22D.

The first transistor 210 is formed by the process described above. Subsequently, the second transistor 220 arranged above the first transistor 210 is formed. In the present embodiment, the configuration of the second transistor 220 is the same as the configuration of the first transistor 210. Therefore, description of a method for forming the second transistor 220 similar to that of the first transistor 210 will be omitted as appropriate.

As shown in FIG. 3 and FIG. 10, the third insulating films 28 and 32 are formed above the second insulating film 24, the second gate electrode 26GE-1, and the third gate electrode 26GE-2 (“3rd IF film formation” in a step S1012 shown in FIG. 2). With respect to the method for forming the third insulating films 28 and 32 and the insulating material, the description of the materials of the first insulating films 14 and 16 may be referred to. In the present embodiment, for example, silicon nitride is formed as the third insulating film 28, and silicon oxide is formed as the third insulating film 32. The third insulating films 28 and 32 may function as the interlayer insulating film of the first transistor 210 and may function as the third gate insulating film of the second transistor 220.

As shown in FIG. 3 and FIG. 10, a second oxide semiconductor film 33 is formed above the third insulating film 32 (“2nd OS film formation” in a step S1013 shown in FIG. 3). With respect to a method and a material for forming the second oxide semiconductor film 33. an explanation of the method and the material for forming the first oxide semiconductor film 17 may be referred to (step S1003 shown in FIG. 2). Although a target of the second oxide semiconductor film 33 is preferably the same target as that of the first oxide semiconductor film 17, a different target may be used.

As shown in FIG. 3 and FIG. 11, a pattern of a second oxide semiconductor layer 34 is formed (“2nd OS pattern formation” in a step S1014 shown in FIG. 3). With respect to an etching method of the second oxide semiconductor film 33, an explanation of an etching method of the first oxide semiconductor film 17 may be referred to (step S1004 shown in FIG. 2).

As shown in FIG. 3 and FIG. 12, the second oxide semiconductor layer 34 is subjected to the heat treatment (OS annealing) (“2nd OS annealing” in a step S1015 shown in FIG. 3) after the second oxide semiconductor layer 34 is patterned. With respect to the conditions for the OS annealing, the conditions for OS annealing with respect to the first oxide semiconductor layer 18 may be referred to (step S1005 shown in FIG. 2). The second oxide semiconductor layer 34 is crystallized by performing the OS annealing, and the second oxide semiconductor layer 36 having a polycrystalline structure is formed. The first oxide semiconductor layer 22 has a high margin for the heating process as described above. Therefore, as the annealing condition of the second oxide semiconductor layer 34, a condition optimized for the second oxide semiconductor layer 34 can be used without worrying about the influence of an addition of a thermal history to the first oxide semiconductor layer 22. As an example, conditions of the 2nd annealing may be the same as the conditions of the annealing of the first oxide semiconductor layer 22.

As shown in FIG. 3 and FIG. 13, the fourth insulating film 38 is formed above the third insulating film 32 and the second oxide semiconductor layer 36 (“4th IF film formation” in a step S1016 shown in FIG. 3). A method for forming the fourth insulating film 38 and the insulating material may be described with reference to the method of forming the second insulating film 24 and the description of the insulating material.

As shown in FIG. 3 and FIG. 13, a second metal oxide film 42 is formed above the fourth insulating film 38 (“2nd MO film formation” in a step S1017 shown in FIG. 3). A method and a material for forming the second metal oxide film 42 may be described with reference to the method and the material for forming the first metal oxide film 25.

With the fourth insulating film 38 and the second metal oxide film 42 formed above the second oxide semiconductor layer 36, a heat treatment (oxidation annealing) for supplying oxygen from the fourth insulating film 38 to the second oxide semiconductor layer 36 is performed (“oxidation annealing” in a step S1018 of steps shown in FIG. 3). With respect to the oxidation annealing, the explanation of “oxidation annealing” in the step S1008 shown in FIG. 2 may be referred to.

As shown in FIG. 3, a second metal oxide film 41 is removed (“2nd MO removal” in a step S1019 shown in FIG. 3).

As shown in FIG. 3, contact holes are formed in the second insulating film 24, the third insulating films 28 and 32, and the fourth insulating film 38 (“contact opening” in a step S1020 shown in FIG. 3). As a result, the first source region 22S and the first drain region 22D of the first oxide semiconductor layer 22 are exposed.

As shown in FIG. 3 and FIG. 14, the first source electrode 44S, the first drain electrode 44D, and the fourth gate electrode 44GE are formed above the fourth insulating film 38 (“1st SD, 4th GE formation” in a step S1021 shown in FIG. 3). The first source electrode 44S, the first drain electrode 44D, and the fourth gate electrode 44GE are formed by processing a conductive film formed by a sputtering method. The first source electrode 44S is connected to the first source region 22S and connected to the first drain region 22D. In addition, the fourth gate electrode 44GE is formed in a region overlapping the second oxide semiconductor layer 36. With respect to a material that can be used for the first source electrode 44S, the first drain electrode 44D, and the fourth gate electrode 44GE, the description of the material of the first gate electrode 12GE may be referred to.

As shown in FIG. 3 and FIG. 15, an impurity element is added to the second oxide semiconductor layer 36 using the fourth gate electrode 44GE as a mask (“2nd I/I” in a step S1022 shown in FIG. 3). The step S1010 shown in FIG. 2 may be referred to as ion-implantation.

The second transistor 220 is formed by the above process.

As shown in FIG. 3 and FIG. 16, the fifth insulating films 46 and 48 are formed above the fourth insulating film 38, the first source electrode 44S, the first drain electrode 44D, and the fourth gate electrode 44GE (“5th IF film formation” in a step S1023 shown in FIG. 3). With respect to the fifth insulating films 46 and 48, the material of the first insulating films 14 and 16 may be referred to. In the present embodiment, for example, silicon nitride is formed as the fifth insulating film 46, and silicon oxide is formed as the fifth insulating film 48. The fifth insulating films 46 and 48 function as interlayer insulating films of the second transistor 220.

As shown in FIG. 3, contact holes are formed in the fifth insulating films 46 and 48 (“contact opening” in a step S1024 shown in FIG. 3). As a result, the first source electrode 44S, the first drain electrode 44D, the second source region 36S and the second drain region 36D of the second oxide semiconductor layer 36 are exposed.

Finally, as shown in FIG. 3 and FIG. 17, the first electrode 52E-1, the second electrode 52E-2, the second source electrode 52S, and the second drain electrode 52D are formed above the fifth insulating film 48 (“2nd SD formation” in a step S1025 shown in FIG. 3). The first electrode 52E-1, the second electrode 52E-2, the second source electrode 52S, and the second drain electrode 52D are formed by processing a conductive film formed by a sputtering method. The first electrode 52E-1 is connected to the first source electrode 44S, and the second electrode 52E-2 is connected to the first drain electrode 44D. The second source electrode 52S is connected to the second source region 36S, and the second drain electrode 52D is connected to the second drain region 36D. With respect to the material that can be used for the first electrode 52E-1, the second electrode 52E-2, the second source electrode 52S, and the second drain electrode 52D, the description of the material of the first gate electrode 12GE may be referred to.

The semiconductor device 100 shown in FIG. 1 can be manufactured by the above process.

In the case where two transistors having different semiconductor materials are stacked, for example, even if both the transistor using crystalline silicon and the transistor using an oxide semiconductor have the same top-gate structure, the structure and the film thickness of the insulating material and the conductive material used in the transistor using low-temperature silicon and the transistor using an oxide semiconductor are different from each other, and thus it is difficult to make the manufacturing process common.

On the other hand, in the semiconductor device 100 according to an embodiment of the present invention, since the two transistors, the first transistor 210 and the second transistor 220, having the same semiconductor material are stacked, it is easy to share the manufacturing process of the two transistors. Therefore, the second transistor 220 can be manufactured by a manufacturing process similar to the manufacturing process of the first transistor 210. In addition, since the interlayer insulating film arranged above the first transistor 210 and the third gate insulating film of the second transistor 220 can be shared as the third insulating films 28 and 32, the manufacturing process can be simplified. Therefore, the manufacturing cost of the semiconductor device 100 can be reduced.

In the semiconductor device 100 according to an embodiment of the present invention, in the case where an oxide semiconductor material is used as each of the first oxide semiconductor layer used for the first transistor and the first oxide semiconductor layer used for the second transistor, a different oxide semiconductor material may be used. For example, Poly-OS may be used as the first oxide semiconductor layer of the first transistor, and IGZO may be used as the second oxide semiconductor layer of the second transistor.

Since the transistor using Poly-OS has a margin for the heating process, the characteristics of the first transistor 210 can be maintained even if a process of the second transistor 220 is formed using a process similar to the process of the first transistor 210. On the other hand, the transistor using IGZO is preferably used as the second transistor 220 because a margin for the heating process is narrower than that of the transistor using Poly-OS. The crystallinity of IGZO is not particularly limited, and may be amorphous or may have crystallinity. The structure of the second transistor is not limited to the top-gate structure, and may be a bottom-gate structure or a dual-gate structure. Further, an impurity element may be added as appropriate depending on the structure of the second transistor 220.

### Modification 1

FIG. 17 is a cross-sectional view showing a semiconductor device 100A partially differing from the semiconductor device 100. As shown in FIG. 17, the device 100A includes a third transistor 230 in addition to the first transistor 210 and the second transistor 220. The third transistor 230 is arranged above the substrate 10 in the same manner as the first transistor 210.

The third transistor 230 includes a fifth gate electrode 12GE-2, the first insulating films 14 and 16, a third oxide semiconductor layer 22-2, the second insulating film 24, and a sixth gate electrode 26GE-3. The third oxide semiconductor layer 22-2 has a third channel region 22CH-2, a third source region 22S-2, and a third drain region 22D-2. In FIG. 17, only a third channel region 36CH-3 and the third source region 22S-2 are shown for the third oxide semiconductor layer 22-2. In addition, in FIG. 20, in order to distinguish from the third oxide semiconductor layer 22-2, the oxide semiconductor layer included in the first transistor 210 is referred to as a first oxide semiconductor layer 22-1.

The third transistor 230 is formed by the same process as the first transistor 210. Therefore, the third oxide semiconductor layer 22-2 includes a first region overlapping the sixth gate electrode 26GE-3 and having the first crystal structure, and a second region not overlapping the sixth gate electrode 26GE-3 and having the second crystal structure. Here, the first region corresponds to the third channel region 22CH-2. The second region corresponds to the first source region 22S and the first drain region 22D. The electrical conductivity of the second region is greater than the electrical conductivity of the first region. In addition, the second crystal structure is the same as the first crystal structure.

The second transistor 220 is arranged above the first transistor 210 and the third transistor 230. The second transistor 220 may overlap a portion of the first transistor 210 and a portion of the third transistor 230. That is, the second source region 36S of the second oxide semiconductor layer 36 overlaps the first drain region 22D-1 of the first oxide semiconductor layer 22-1, and the second drain region 36D of the second oxide semiconductor layer 36 overlaps the third source region 22S-2 of the third oxide semiconductor layer 22-2.

In the semiconductor device 100A according to an embodiment of the present disclosure, the second transistor 220, the first transistor 210, and the third transistor 230 may overlap with each other. Thus, for example, in the case where the semiconductor device 100 is applied to a pixel circuit or a drive circuit, the circuit region can be reduced. That is, the semiconductor device 100 can be further integrated.

In the present embodiment, although the example has been described in which the second source region 36S of the second transistor 220 and the first drain region 22D of the first transistor 210 overlap each other, an embodiment of the present invention is not limited thereto. Although not shown, the second source region 36S may overlap at least a portion of the first channel region 22CH of the first transistor 210. In addition, the third gate electrode 26GE-2 may overlap the first drain region 22D-1. The first gate electrode 12GE (or a gate wiring connected to the first gate electrode 12GE) may overlap the second source region 36S. In this way, in the semiconductor device 100A, in the case where the first transistor 210 and the second transistor 220 overlap each other, structural constraints can be reduced as described above.

### Second Embodiment

In the present embodiment, a semiconductor device 100B that partially differs from the semiconductor device 100 described in the first embodiment will be described.

### Configuration of Semiconductor Device 100B

FIG. 18 is a cross-sectional view schematically showing the semiconductor device 100B according to an embodiment of the present disclosure.

As shown in FIG. 18, the device 100B includes a first transistor 210A and a second transistor 220A arranged above the substrate 10. A configuration of the first transistor 210A is the same as that of the first transistor 210, except that a first metal oxide layer 52 is arranged between the first oxide semiconductor layer 22 and the first insulating film 16. Further, a configuration of the second transistor 220A is the same as that of the second transistor 220, except that a second metal oxide layer 54 is arranged between the second oxide semiconductor layer 36 and the third insulating film 32. Although not shown, as described with reference to FIG. 17, in the case where the third transistor 230 is formed above the same plane as the first transistor 210 above the substrate 10, a third metal oxide layer below the third oxide semiconductor layer is arranged.

As the first metal oxide layer 52 and the second metal oxide layer 54, a metal oxide containing aluminum as a main component is used. As the first metal oxide layer 52 and the second metal oxide layer 54, the same material as that of the first metal oxide film 25 can be used. For example, thicknesses of the first metal oxide layers 52 and the second metal oxide layers 54 are 1 nm or more and 100 nm or less, 1 nm or more and 50 nm or less, 1 nm or more and 30 nm or less, or 1 nm or more and 10 nm or less. In the present embodiment, aluminum oxide is used as the first metal oxide layer 52 and the second metal oxide layer 54. Aluminum oxide has a high barrier property against gas. In the present embodiment, the aluminum oxide used as the first metal oxide layer 52 and the second metal oxide layer 54 blocks the hydrogen and oxygen released from the first insulating film 16 and the third insulating film 32, and suppresses the released hydrogen and oxygen from reaching the first oxide semiconductor layer 22 and the second oxide semiconductor layer 36.

When oxygen is excessively supplied to the first oxide semiconductor layer 22 and the second oxide semiconductor layer 36, a defect level different from the oxygen defect is formed by the excessive oxygen. This may cause a phenomenon such as the characteristic variation due to the reliability test, the decrease in field-effect mobility, or the variation in characteristics.

The excessive oxygen can be suppressed from being supplied to the lower surfaces of the first oxide semiconductor layer 22 and the second oxide semiconductor layer 36 by providing the first metal oxide layer 52 and the second metal oxide layer 54 below the first oxide semiconductor layer 22 and the second oxide semiconductor layer 36. As a result, it is possible to suppress formation of the defect level above the lower surfaces of the first oxide semiconductor layer 22 and the second oxide semiconductor layer 36. Therefore, it is possible to suppress a characteristic variation, a decrease in field-effect mobility, or a variation in characteristics due to a reliability test of the first transistor 210A and the second transistor 220A.

### Process for Manufacturing Semiconductor Device 100B

Referring to FIG. 19 to FIG. 23, the semiconductor device 100B according to an embodiment of the present disclosure will be described. FIG. 19 and FIG. 20 are sequential diagrams showing methods for manufacturing the semiconductor device 100B according to an embodiment of the present disclosure. FIG. 21 to FIG. 23 are cross-sectional views showing methods for manufacturing the semiconductor device 100B according to an embodiment of the present disclosure. Further, detailed description of the same processes as those of the first embodiment will be omitted.

As shown in FIG. 19, the processes of a step S1101 to a step S1102 are the same as the processes of the step S1001 to the step S1002 shown in FIG. 2.

In the present embodiment, as shown in FIG. 19 and FIG. 21, after the process of the step S1102, a first metal oxide film 51 containing aluminum as a main component is formed above the first insulating film 16 (“1st MO film formation” in a step S1103 shown in FIG. 19).

The first metal oxide film 51 is formed by a sputtering method or an atomic layer deposition method. For example, a thickness of the first metal oxide film 51 is 1 nm or more and 50 nm or less, 1 nm or more and 30 nm or less, 1 nm or more and 20 nm or less, or 1 nm or more and 10 nm or less. In the present embodiment, aluminum oxide is used as the first metal oxide film 51. Aluminum oxide has a high barrier property against gases such as oxygen or hydrogen. In the present embodiment, the aluminum oxide used as the first metal oxide film 51 blocks the hydrogen and oxygen released from the first insulating film 16, and suppresses the released hydrogen and oxygen from reaching the first oxide semiconductor layer 22 to be formed later.

As shown in FIG. 19 and FIG. 21, the first oxide semiconductor film 17 is formed above the first metal oxide film 51 (“1st OS film formation” in a step S1104 shown in FIG. 19). With respect to a method and a material for forming the first oxide semiconductor film 17 in the present embodiment, the method and the material for forming the first oxide semiconductor film 17 may be referred to (step S1003 shown in FIG. 2).

As shown in FIG. 19, a pattern of the first oxide semiconductor layer is formed (“1^{st} OS pattern formation” in a step S1105 shown in FIG. 19). A resist mask is formed above the first oxide semiconductor film 17, and the first oxide semiconductor film 17 is etched using the resist mask. With respect to an etching method of the first oxide semiconductor film 17 in the present embodiment, the explanation of the etching method of the first oxide semiconductor film 17 may be referred to (step S1004 shown in FIG. 2).

Next, the first oxide semiconductor layer 18 is subjected to the heat treatment (OS annealing) (“1st OS annealing” in a step S1106 shown in FIG. 9) after the first oxide semiconductor layer 18 is patterned. With respect to the conditions of the OS annealing, the explanation of the conditions of OS annealing for the first oxide semiconductor layers 18 may be referred to (step S1005 shown in FIG. 2). In addition, conditions of the OS annealing for the second oxide semiconductor layer 34 may be the same as the conditions of the OS annealing for the first oxide semiconductor layer 18. As shown in FIG. 19 and FIG. 22, the first oxide semiconductor layer 18 is crystallized to form the first oxide semiconductor layer 22 having the polycrystalline structure by performing the OS annealing.

As shown in FIG. 19 and FIG. 23, the first metal oxide film 51 is patterned to form the first metal oxide layer 52 (“1st MO pattern formation” in a step S1107 shown in FIG. 19). The first oxide semiconductor layer 22 sufficiently crystallized by the heat treatment has etching resistance. Therefore, it is possible to prevent the first oxide semiconductor layer 22 from disappearing when the first metal oxide film 51 is patterned using the crystallized first oxide semiconductor layer 22 as a mask. The first metal oxide film 51 is etched using the first oxide semiconductor layer 22 patterned in the process described above as the mask. As the etching of the first metal oxide film 51, wet etching may be used, or dry etching may be used. For example, dilute hydrofluoric acid (DHF) is used as the wet etching. A photolithography process can be omitted by etching the first metal oxide film 51 using the first oxide semiconductor layer 22 as the mask.

Thereafter, since the processes shown in a step S1108 to a step S1109 shown in FIG. 19 are the same as the processes shown in the step S1006 to the step S1007 shown in FIG. 2, detailed explanation will be omitted.

As shown in FIG. 19, in the state where the second insulating film 24 and the first metal oxide film 25 are formed above the first oxide semiconductor layer 22, the heat treatment (oxidation annealing) for supplying oxygen from the second insulating film 24 to the first oxide semiconductor layer 22 is performed (“oxidation annealing” in a step S1110 shown in FIG. 19).

In the present embodiment, the first metal oxide layer 52 is arranged below the first oxide semiconductor layer 22. In this state, if the oxidation annealing is performed, the oxygen released from the first insulating film 16 is blocked by the first metal oxide layer 52, so that the oxygen is hardly supplied to a lower surface of the first oxide semiconductor layer 22. Oxygen emitted from the first insulating film 16 diffuses from a region where the first metal oxide layer 52 is not formed to the second insulating film 24 arranged above the first insulating film 16, and reaches the first oxide semiconductor layer 22 via the second insulating film 24. As a result, the oxygen emitted from the first insulating film 16 is hardly supplied to the lower surface of the first oxide semiconductor layer 22, and is mainly supplied to the side surface and the upper surface of the first oxide semiconductor layer 22. Further, oxygen released from the second insulating film 24 is supplied to the upper surface and the side surface of the first oxide semiconductor layer 22 by the oxidation annealing. Although there is a case where hydrogen may be released from the first insulating films 14 and 16 by the oxidation annealing, the hydrogen is blocked by the first metal oxide layer 52.

As described above, oxygen can be supplied to the upper surface and the side surface of the first oxide semiconductor layer 22 having a large amount of oxygen defects while suppressing the supply of oxygen to the lower surface of the first oxide semiconductor layer 22 having a small amount of oxygen defects by the oxidation annealing process.

Thereafter, the processes shown in a step S1111 to a step S1114 shown in FIG. 19 are the same as the processes shown in the step S1009 to the step S1012 shown in FIG. 2.

The processes shown in a step S1115 to a step S1123 shown in FIG. 20 are the same as the processes shown in the step S1103 to the step S1111 shown in FIG. 19.

The processes shown in a step S1124 to a step S1129 shown in FIG. 20 are the same as the processes shown in step S1020 to the step S1025 shown in FIG. 3.

Through the above processes, the semiconductor device 100B shown in FIG. 18 can be manufactured.

In the semiconductor device 100B manufactured by the manufacturing method described above, oxygen defects included in the first oxide semiconductor layer 22 and the second oxide semiconductor layer 36 can be further reduced as compared with the manufacturing method of the semiconductor device 100 described in the first embodiment. Therefore, in the semiconductor device 100B described in the present embodiment, it is possible to obtain an electric property having a mobility of 50 cm²/Vs or more, 55 cm²/Vs or more, or 60 cm²/Vs or more in a region in which channel lengths L of channel regions CH of the first transistor 210A and the second transistor 220A are 2 μm or more and 4 μm or less and channel widths of the channel regions CH are 2 μm or more and 25 μm or less.

In addition, it is possible to prevent excessive oxygen from being supplied to the lower surfaces of the first oxide semiconductor layer 22 and the second oxide semiconductor layer 36. In particular, the oxygen defects contained in the channel region CH are sufficiently reduced, so that it is possible to suppress the trapping of hydrogen in the oxygen defects. As a result, since characteristic fluctuations in reliability tests of the first transistor 210A and the second transistor 220A can be reduced, the reliability of the semiconductor device is improved.

In addition, the second transistor 220A can be formed without significant change in the process of forming the first transistor 210A. Therefore, it is possible to reduce a manufacturing cost in the manufacturing method of the device 100B.

### Modification 2

In the manufacturing process of the semiconductor device 100B, the processes shown in the steps S1109 and S1110 shown in FIG. 19 and the processes shown in the steps S1121 and S1123 shown in FIG. 20 may be omitted. In this case, oxidation annealing is performed in a state where the first metal oxide film 25 is not formed above the second insulating film 24. Even in this state, oxygen is supplied from the second insulating film 24 arranged above the first oxide semiconductor layer 22. Further, since the first metal oxide layer 52 is arranged below the first oxide semiconductor layer 22, it is possible to prevent excessive oxygen from being supplied to the lower surface of the first oxide semiconductor layer 22. Therefore, in the range where the channel length L of the channel region CH of the first transistor 210 is 2 μm or more and 4 μm or less and the channel width of the channel region CH is 2 μm or more and 25 μm or less, it is possible to obtain an electric property having a mobility of 30 cm²/Vs or more, 35 cm²/Vs or more, or 40 cm²/Vs or more. In addition, the same characteristics as those of the first transistor 210 can be obtained for the second transistor 220.

### Modification 3

In the semiconductor device according to an embodiment of the present disclosure, the first transistor 210 (see FIG. 1) and the second transistor 220A (see FIG. 18) may be combined and configured above the substrate 10. In this case, the processes shown in the steps S1001 to S1012 may be performed, and then the processes shown in the step S1115 to the step S1129 shown in FIG. 20 may be performed.

In the semiconductor device according to an embodiment of the present disclosure, the first transistor 210A (see FIG. 18) and the second transistor 220 (see FIG. 1) may be combined and configured above the substrate 10. In this case, the processes shown in the steps S1101 to S1114 may be performed in the sequence showing the method for manufacturing the semiconductor device shown in FIG. 19, and then the processes shown in the step S1013 to the step S1025 shown in FIG. 3 may be performed.

As described above, in a method for manufacturing a semiconductor device according to an embodiment of the present invention, it is possible to stack two types of transistors having different mobilities without significantly changing the process. Therefore, it is possible to reduce the manufacturing cost in the manufacturing method of the device 100B.

In addition, in the first embodiment and the second embodiment, although an embodiment of the present invention has been described using the top-gate structure as the first transistor 210 and second transistor 220, an embodiment of the present invention is not limited thereto. A staggered transistor structure may be used as the first transistor 210 and the second transistor 220.

### Third Embodiment

A display device 20 using the semiconductor device 100 according to an embodiment of the present invention will be described with reference to FIG. 24 to FIG. 27. First, a configuration in which the semiconductor device 100 is applied to a circuit of a liquid crystal display device will be described.

### Overview of the Display Device 20

FIG. 24 is a plan view showing an outline of the display device 20 according to an embodiment of the present invention. As shown in FIG. 24, the display device 20 includes an array substrate 300, a sealing portion 310, a counter substrate 320, a flexible printed circuit board 330 (FPC330), and an IC tip 340. The array substrate 300 and the counter substrate 320 are bonded to each other by the sealing portion 310. In a liquid crystal region 23 surrounded by the seal portion 310, a plurality of pixel circuits 301 are arranged in a matrix. The liquid crystal region 23 is a region overlapping a liquid crystal element 311 described later in a plan view.

A seal region 21 in which the seal portion 310 is arranged is a region around the liquid crystal region 23. The FPC 330 is arranged in a terminal region 27. The terminal region 27 is a region where the array substrate 300 is exposed from the counter substrate 320, and is arranged outside the seal region 21. The outside of the seal region 21 means the outside of the region where the seal portion 310 is arranged and a region surrounded by the seal portion 310. The IC chip 340 is arranged above the FPC 330. The IC chip 340 is configured to drive the pixel circuits 301.

### Circuit Configuration of Display Device 20

FIG. 25 is a block diagram showing a circuit configuration of the display device 20 according to an embodiment of the present invention. As shown in FIG. 25, a source driver circuit 302 is arranged at a position adjacent to the liquid crystal region 23 in which the pixel circuit 301 is arranged in a second direction D2 (column direction), and a gate driver circuit 303 is arranged at a position adjacent to the liquid crystal region 23 in a first direction D1 (row direction). The source driver circuit 302 and the gate driver circuit 303 are arranged in the sealing region 21. However, the region in which the source driver circuit 302 and the gate driver circuit 303 are arranged is not limited to the seal region 21, and any region may be used as long as it is outside the region in which the pixel circuit 301 is arranged.

A source wiring 304 extends from the source driver circuit 302 in the second direction D2 and is connected to the plurality of pixel circuits 301 arranged in the second direction D2. A gate electrode 160 extends from the gate driver circuit 303 in the first direction D1 and is connected to the plurality of pixel circuits 301 arranged in the first direction D1.

A terminal part 306 is arranged in the terminal region 27. The terminal part 306 and the source driver circuit 302 are connected by a connecting wiring 307. Similarly, the terminal part 306 and the gate driver circuit 303 are connected by the connecting wiring 307. An external device to which the FPC 330 is connected and the display device 20 are connected by connecting the FPC 330 to the terminal part 306, and each of the pixel circuits 301 arranged in the display device 20 is driven by a signal from the external device.

The semiconductor device 100 can be applied to the pixel circuit 301, the source driver circuit 302, and the gate driver circuit 303. The semiconductor device 100 can be applied to the source driver circuit 302 and the gate driver circuit 303 to overlap the first transistor 210 and the second transistor 220. Therefore, even in the case of the source driver circuit 302 and the gate driver circuit 303 having a high degree of integration, occupied regions can be reduced. This makes it possible to reduce a frame size of the display device 20. In addition, although the semiconductor device 100 is applied to the source driver circuit 302 and the gate driver circuit 303, the semiconductor devices 100A and 100B may be applied to the source driver circuit 302 and the gate driver circuit 303.

### Pixel Circuit 301 of Liquid Crystal Display Device

Next, a case where the semiconductor device 100 is applied to a pixel circuit of a liquid crystal display device will be described. FIG. 26 is a circuit diagram showing a pixel circuit of the display device 20 according to an embodiment of the present invention. As shown in FIG. 26, the pixel circuit 301 includes elements such as the first transistor 210, a storage capacitor 350, and the liquid crystal element 311. The first transistor 210 includes the gate electrode 160, a source electrode 201, and a drain electrode 203. The gate electrode 160 is connected to a gate wiring 305. The source electrode 201 is connected to the source wiring 304. The drain electrode 203 is connected to one end of the storage capacitor 350 and one end (pixel electrode) of the liquid crystal element 311. In the present embodiment, for convenience of explanation, although the electrode indicated by reference numeral “201” is referred to as a source electrode and the electrode indicated by reference numeral “203” is referred to as a drain electrode, the electrode indicated by reference numeral “201” may function as a drain electrode, and the electrode indicated by reference numeral “203” may function as a source electrode.

In the first transistor 210, the second gate electrode 26GE-1 corresponds to the gate electrode 160, the first source electrode 44S corresponds to the source electrode 201, and the first drain electrode 44D corresponds to the drain electrode 203. The first gate electrode 12GE may function as a back gate of the first transistor 210 or may float the first gate electrode 12GE.

In the case where the second transistor 220 is used in the pixel circuit 301, the fourth gate electrode 44GE corresponds to the gate electrode 160, the second source electrode 52S corresponds to the source electrode 201, and the second drain electrode 52D corresponds to the drain electrode 203. The third gate electrode 26GE-2 may function as a back gate of the second transistor 220 or may float the third gate electrode 26GE-2.

As described in the previous embodiment, the first transistor 210 and the second transistor 220 may overlap each other. Therefore, the first transistor 210 and the second transistor 220 can overlap above each other by applying the first transistor 210 and the second transistor 220 to adjacent pixels. As a result, occupied regions by the first transistor 210 and the second transistor 220 in the pixel are reduced, so that an aperture ratio of the pixel can be improved. In addition, although a case where the semiconductor device 100 is applied to the pixel circuit is described in FIG. 26, the semiconductor devices 100A and 100B may be applied to the pixel circuit.

### Pixel Circuit 301 of EL Display Device

Next, a case where the semiconductor device 100 described in the first embodiment is applied to a circuit of an organic EL display device will be described. An outline and a circuit configuration of the display device 20 are the same as those shown in FIG. 24 and FIG. 25, and thus descriptions thereof will be omitted.

FIG. 27 is a circuit diagram showing a pixel circuit of the display device 20 according to an embodiment of the present invention. As shown in FIG. 27, the pixel circuit 301 includes elements such as a select transistor 11, a driving transistor 13, the storage capacitor 350, and a light emitting element DO. Here, a case where the first transistor 210 is applied to the selection transistor 11 and the second transistor 220 is applied to the driving transistor 13 will be described.

A source electrode of the selection transistor 11 is connected to a signal line 211, and a gate electrode of the selection transistor 11 is connected to the gate line 212. A source electrode of the driving transistor 13 is connected to an anode power supply line 213, and a drain electrode of the driving transistor 13 is connected to one end (pixel electrode) of the light emitting device DO. The other end of the light emitting device DO is connected to a cathode power supply line 214. A gate electrode of the driving transistor 13 is connected to a drain electrode of the selection transistor 11. The storage capacitor 350 is connected to the gate electrode and the drain electrode of the driving transistor 13. The signal line 211 is supplied with a gradation signal that determines emission intensity of the light emitting device DO. The gate line 212 is supplied with a signal for selecting a pixel row for writing the gradation signal.

The second gate electrode 26GE-1 of the first transistor 210 corresponds to the gate electrode of the selection transistor 11, the first source electrode 44S corresponds to the source electrode of the selection transistor 11, and the first drain electrode 44D corresponds to the drain electrode of the selection transistor 11. The first gate electrode 12GE may function as a back gate of the first transistor 210 or may float the first gate electrode 12GE.

The fourth gate electrode 44GE of the second transistor 220 corresponds to the gate electrode 160 of the driving transistor 13, the second source electrode 52S corresponds to the source electrode 201 of the driving transistor 13, and the second drain electrode 52D corresponds to the drain electrode 203 of the driving transistor 13. The third gate electrode 26GE-2 may function as a back gate of the second transistor 220 or may float the third gate electrode 26GE-2.

In FIG. 27, although a case in which the lower first transistor 210 is applied to the selection transistor 11 and the upper second transistor 220 is applied to the driving transistor 13 has been described, the transistor to which the embodiment of the present invention is applied is not limited. For example, the second transistor 220 in the upper layer may be applied to the selection transistor 11, and the first transistor 210 in the lower layer may be applied to the driving transistor 13. In addition, the number of transistors constituting the pixel circuit is not limited in the EL display devices. The number of transistors constituting the pixel circuit may be three or more. Therefore, some of the plurality of transistors constituting the pixel circuit may be arranged in the lower layer, and the remaining transistors may be arranged in the upper layer. As a result, a plurality of transistors can be formed in a small area, and thus high definition can be achieved.

In the third embodiment, although a configuration in which the semiconductor device described in the first embodiment is applied to the liquid crystal display device and the organic EL display device has been exemplified, the semiconductor device may be applied to a display device other than these display devices (for example, a self-luminous display device or an electronic paper type display device other than the organic EL display device). Further, the semiconductor device 100 can be applied from a medium-sized display device to a large-sized display device without any particular limitation. In addition, although the semiconductor device 100 is applied to the pixel circuit in FIG. 27, the semiconductor devices 100A and 100B may be applied to the pixel circuit.

The embodiments and the modifications described above as the embodiments of the present invention can be appropriately combined and implemented as long as they do not conflict with each other. Further, based on the semiconductor device and the display device of each of the embodiments and the modification, additions, deletions, or design changes to components or additions, omissions, or condition changes of the processes made by those skilled in the art as appropriate are included in the scope of the present invention as long as they have the gist of the present invention.

It is to be understood that other operational effects that are different from the operational effects provided by the aspects of the embodiments described above, and those that are obvious from the description of the present specification or those that can be easily predicted by a person skilled in the art are brought about by the present invention.

What is claimed is:

1. A semiconductor device comprising:
a first transistor arranged on a substrate; and
a second transistor arranged on the first transistor,
wherein the first transistor comprises:
a first gate electrode arranged on the substrate;
a first insulating film arranged on the first gate electrode;
a first oxide semiconductor layer arranged on the first insulating film, having a region overlapping the first gate electrode, and having a polycrystalline structure;
a second insulating film arranged on the first oxide semiconductor layer; and
a second gate electrode arranged on the second insulating film,
wherein the second transistor comprises:
a third gate electrode arranged on the second insulating film;
a third insulating film arranged on the third gate electrode;
a second oxide semiconductor layer arranged on the third insulating film and having a region overlapping the third gate electrode;
a fourth insulating film arranged on the second oxide semiconductor layer; and
a fourth gate electrode arranged on the fourth insulating film.

2. The semiconductor device according to claim 1, wherein
the first oxide semiconductor layer includes a first region overlapping the first gate electrode and having a first crystal structure and a second region not overlapping the first gate electrode and having a second crystalline structure, and
an electrical conductivity of the second region is greater than an electrical conductivity of the first region.

3. The semiconductor device according to claim 2, wherein
the second oxide semiconductor layer has a polycrystalline structure, a third region overlapping the second gate electrode and having the first crystalline structure, and a fourth region overlapping the second gate electrode and having the second crystalline structure,
an electrical conductivity of the fourth region is greater than an electrical conductivity of the third region, and
the second crystal structure is identical to the first crystal structure.

4. The semiconductor device according to claim 3, wherein
the second region of the first oxide semiconductor layer and the fourth region of the second oxide semiconductor layer overlap in a plan view.

5. The semiconductor device according to claim 1, further comprising:
a third transistor arranged on the substrate,
wherein the third transistor comprises:
a fifth gate electrode arranged on the substrate;
the first insulating film arranged on the fifth gate electrode;
a third semiconductor layer arranged on the first insulating film and having a region overlapping the gate electrode;
the second insulating film arranged on the third oxide semiconductor layer; and
a sixth gate electrode arranged on the second insulating film.

6. The semiconductor device according to claim 5, wherein
the third oxide semiconductor layer includes a fifth region overlapping the fifth gate electrode and having a first crystal structure, and a sixth region not overlapping the fifth gate electrode and having a second crystalline structure,
an electrical conductivity of the sixth region is greater than an electrical conductivity of the fifth region, and
the second crystal structure is identical to the first crystal structure.

7. The semiconductor device according to claim 6, wherein
the fourth region of the second oxide semiconductor layer overlaps the second region in the first oxide semiconductor layer and the sixth region in the third oxide semiconductor layer in a plan view.

8. The semiconductor device according to claim 1, further comprising:
a first metal oxide layer arranged between the first insulating film and the first oxide semiconductor layer.

9. The semiconductor device according to claim 1, further comprising:
a second metal oxide layer arranged between the third insulating film and the second oxide semiconductor layer.

10. The semiconductor device according to claim 5, further comprising:
a third metal oxide layer arranged between the first insulating film and the third oxide semiconductor layer.

11. The semiconductor device according to claim 1, wherein
a thickness of the second insulating film is thinner than a thickness of the first insulating film, and
a thickness of the fourth insulating film is thinner than a thickness of the second insulating film.

12. The semiconductor device according to claim 1, wherein
the first transistor further includes a first source electrode and a first drain electrode arranged on the same insulating film as the fourth gate electrode, and
each of the first source electrode and the first drain electrode is connected to the first oxide semiconductor layer via contact holes in the second insulating film, the third insulating film, and the fourth insulating film.

13. The semiconductor device according to claim 1, wherein
each of the first insulating film and the third insulating film has a stacked structure of a silicon nitride film and a silicon oxide film.
